(19) United States
(12) Patent Application Publication
(10) Pub. No.: US 2026/0068388 A1
(43) Pub. Date: Mar. 5, 2026

(54) Display Device and Method of Manufacturing the Same

(71) Applicant: LG Display Co., Ltd., Seoul (KR)

(72) Inventors: Injun Lee, Gimpo-si (KR); Aesun Kim, Paju-si (KR); HaeYoon Jung, Seoul (KR); MyungSub Lim, Seoul (KR); YuRa Jeong, Seoul (KR)

(21) Appl. No.: 19/266,810

(22) Filed: Jul. 11, 2025

(30) Foreign Application Priority Data
Sep. 4, 2024 (KR) 10-2024-0120290

(51) Int. Cl. H10H 29/41; H10H 29/01; H10H 29/49

(52) U.S. Cl. CPC H10H 29/41; H10H 29/012; H10H 29/49

(57) ABSTRACT

Provided are a display device and a method of manufacturing a display device. The display device includes a stretchable lower substrate divided into a first area, and a second area different from the first area; a pattern layer disposed on the lower substrate and including a plate pattern disposed in the first area, and a line pattern disposed in the second area; a first metal layer disposed on the plate pattern and the line pattern; a circuit element layer disposed on the plate pattern and the first metal layer and including at least one transistor; a light-emitting element disposed on the circuit element layer; and a connection line disposed on the line pattern and connected to the circuit element layer. Therefore, the stretching reliability of the display device may be improved.

### CROSS-REFERENCE TO RELATED APPLICATION

This application claims the priority of Republic of Korea Patent Application No. 10-2024-0120290 filed on Sep. 4, 2024, which is hereby incorporated by reference in its entirety.

### BACKGROUND

### Field

The present disclosure relates to a display device and a method of manufacturing the same, and more particularly, to an extendable, stretchable display device and a method of manufacturing the same.

### Description of the Related Art

As display devices used for a monitor of a computer, a television (TV) set, a mobile phone, and the like, there are an organic light-emitting display (OLED) configured to autonomously emit, and a liquid crystal display (LCD) that requires a separate light source.

The range of applications of the display devices is diversified from the monitor of the computer and the TV set to personal mobile devices, and studies are being conducted on the display devices having wide display areas and having reduced volumes and weights.

In addition, recently, display devices have been made by forming display parts, lines, and the like on substrates made of flexible plastic materials and having flexibility. The display devices are manufactured to be stretchable in particular directions and variously changeable in shapes, and thus attract attention as next-generation display devices.

### SUMMARY

An object to be achieved by the present disclosure is to provide a display device, in which damage to a line pattern in which a connection line is disposed is suppressed, and a method of manufacturing the same.

Another object to be achieved by the present disclosure is to provide a display device with improved stretching reliability, and a method of manufacturing the same.

Still another object to be achieved by the present disclosure is to provide a display device with improved resolution, and a method of manufacturing the same.

In order to achieve the above-mentioned objects, a display device according to an embodiment of the present disclosure may include: a stretchable lower substrate divided into a first area, and a second area different from the first area; a pattern layer disposed on the lower substrate and including a plate pattern disposed in the first area, and a line pattern disposed in the second area; a first metal layer disposed on the plate pattern; a circuit element layer disposed on the plate pattern and the first metal layer and including at least one transistor; a light-emitting element disposed on the circuit element layer; and a connection line disposed on the line pattern and connected to the circuit element layer, in which the first metal layer is in an electrically floating state.

In order to achieve the above-mentioned objects, a display device according to an embodiment of the present disclosure may include: a stretchable lower substrate divided into a first area, and a second area different from the first area; a pattern layer disposed on the lower substrate and including a plate pattern disposed in the first area, and a line pattern disposed in the second area; a first metal layer disposed on the plate pattern and the line pattern; a circuit element layer disposed on the plate pattern and the first metal layer and including at least one transistor; a light-emitting element disposed on the circuit element layer; and a connection line disposed on the line pattern and connected to the circuit element layer.

In order to achieve the above-mentioned objects, a method of manufacturing a display device according to still another embodiment of the present disclosure may include: providing a lower substrate divided into a first area, and a second area different from the first area; providing a pattern layer on the lower substrate, the pattern layer including a plate pattern configured to overlap the first area, and a line pattern configured to overlap the second area; providing a first metal layer on the pattern layer, the first metal layer being configured to overlap at least a partial area of the first area and the second area; sequentially providing first insulating material, second insulating material, third insulating material, fourth insulating material, fifth insulating material, sixth insulating material and seventh insulating material on the pattern layer and the first metal layer; forming a seventh insulation layer, a sixth insulation layer, and a fifth insulation layer on the plate pattern by removing the seventh insulating material, the sixth insulating material, and the fifth insulating material disposed in the second area; and forming a fourth insulation layer, a third insulation layer, a second insulation layer, and a first insulation layer on the plate pattern by removing the fourth insulating material, the third insulating material, the second insulating material, and the first insulating material disposed in the second area.

Objects of the present disclosure are not limited to the above-mentioned objects, and other objects, which are not mentioned above, can be clearly understood by those skilled in the art from the following descriptions.

According to the display device and the method of manufacturing the same according to the embodiments of the present disclosure, the process of etching the insulating materials disposed above the line pattern is performed in the state in which the metal layer is disposed above the line pattern, which may inhibit the line pattern and the boundary between the line pattern and the plate pattern from being damaged by the metal layer during the process of etching the insulating material. Therefore, the stretching reliability of the display device may be improved.

In addition, according to the display device and the method of manufacturing the same according to the embodiments of the present disclosure, the line pattern and the boundary between the line pattern and the plate pattern are inhibited from being damaged by the metal layer disposed above the line pattern during the process of etching the insulating material, such that the area, in which the planarization layer is disposed on the plate pattern to reinforce the boundary between the line pattern and the plate pattern, may be minimized, or the planarization layer may be excluded. Therefore, the size and/or area of the plate pattern on which the plurality of pixels is disposed may be reduced, and a high-resolution display device may be implemented.

The effects of the present disclosure are not limited to the aforementioned effects, and other effects, which are not mentioned above, will be apparently understood to a person having ordinary skill in the art from the following description.

The objects to be achieved by the present disclosure, the means for achieving the objects, and the effects of the present disclosure described above do not specify essential features of the claims, and, thus, the scope of the claims is not limited to the disclosure of the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a top plan view illustrating a display device according to embodiments of the present disclosure;

FIG. 2 is an enlarged top plan view illustrating an example of part A in FIG. 1 according to embodiments of the present disclosure;

FIG. 3 is a cross-sectional view illustrating an example taken along line III-III′ illustrated in FIG. 2 according to embodiments of the present disclosure;

FIGS. 4A to 4L are process diagrams illustrating a method of manufacturing the display device according to embodiments of the present disclosure;

FIG. 5 is a view for explaining an example of a protection pattern included in the display device in FIG. 3 according to embodiments of the present disclosure;

FIG. 6 is a view for explaining another example of the protection pattern included in the display device in FIG. 3 according to embodiments of the present disclosure;

FIG. 7 is a cross-sectional view illustrating another example taken along line III-III′ illustrated in FIG. 2 according to embodiments of the present disclosure;

FIG. 8 is a process diagram illustrating a method of manufacturing the display device according to embodiments of the present disclosure;

FIG. 9A is a cross-sectional view illustrating still another example taken along line III-III′ illustrated in FIG. 2 according to embodiments of the present disclosure;

FIG. 9B is a view for explaining an example of a protection pattern included in the display device in FIG. 9A according to embodiments of the present disclosure;

FIG. 10A is a cross-sectional view illustrating yet another example taken along line III-III′ illustrated in FIG. 2 according to embodiments of the present disclosure;

FIG. 10B is a view for explaining an example of a protection pattern included in the display device in FIG. 10A according to embodiments of the present disclosure;

FIG. 11A is a cross-sectional view illustrating still yet another example taken along line III-III′ illustrated in FIG. 2 according to embodiments of the present disclosure;

FIG. 11B is a view for explaining an example of a protection pattern included in the display device in FIG. 11A according to embodiments of the present disclosure;

FIG. 11C is a view for explaining another example of the protection pattern included in the display device in FIG. 11A according to embodiments of the present disclosure;

FIG. 12A is a cross-sectional view illustrating a further example taken along line III-III′ illustrated in FIG. 2 according to embodiments of the present disclosure;

FIG. 12B is a view for explaining an example of a protection pattern included in the display device in FIG. 12A according to embodiments of the present disclosure;

FIGS. 13A to 13D are views for explaining a defective portion of a line pattern included in a display device according to a comparative example of the present disclosure; and

FIGS. 14A and 14B are views for explaining a line pattern included in the display device according to embodiments of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

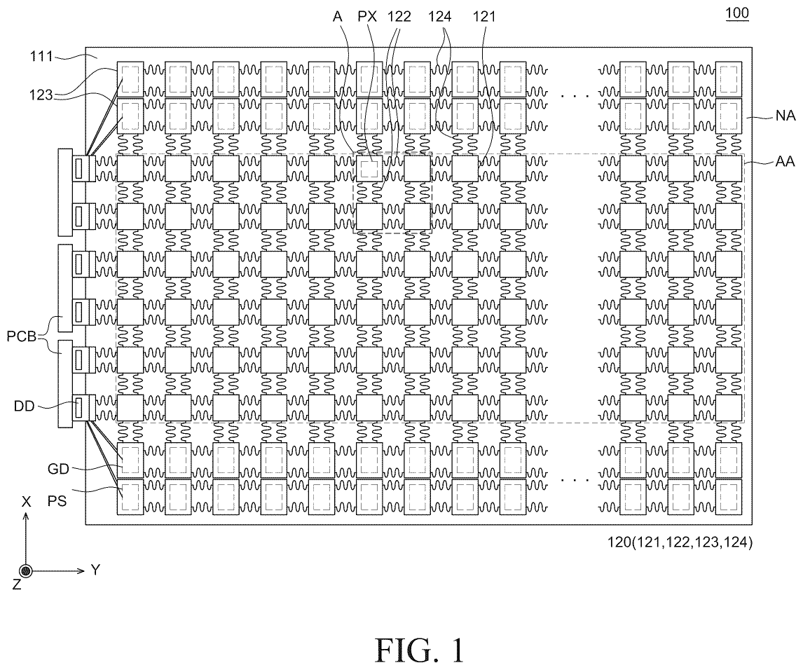

FIG. 1 is a top plan view illustrating a display device according to embodiments of the present disclosure.

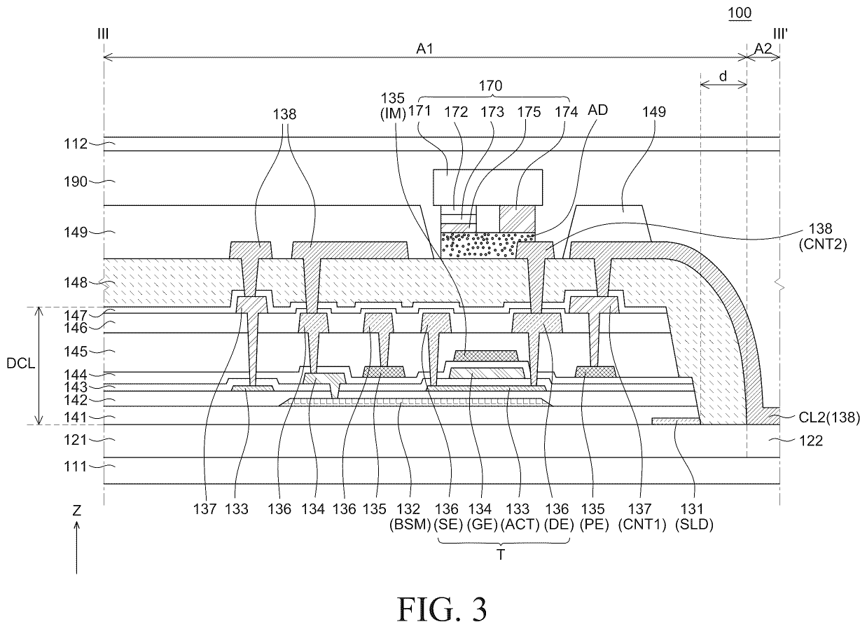

With reference to FIG. 1, a display device 100 according to embodiments of the present disclosure may include a lower substrate 111, a pattern layer 120, a plurality of pixels PX, a gate driver GD, a data driver DD, and a power supply PS. In the embodiment, the display device 100 may further include an upper substrate (e.g., an upper substrate 112 in FIG. 3).

The lower substrate 111 may support several constituent elements of the display device 100, and the upper substrate (e.g., the upper substrate 112 in FIG. 3) may cover several constituent elements of the display device 100. In the embodiment, the lower substrate 111 and the upper substrate 112 may each be a flexible substrate containing an insulating material that is bendable or stretchable.

The lower substrate 111 and the upper substrate 112 may each have an elastic modulus of several MPa to several hundreds of MPa. According to the embodiment, a ductile breaking rate of each of the lower substrate 111 and the upper substrate 112 may be 100% or more. In this case, the ductile breaking rate means an elongation ratio at a time point at which a stretching object breaks or cracks.

The lower substrate 111 may include a display area AA in which images are displayed, and a non-display area NA that excludes the display area AA. For example, the plurality of pixels PX, which each include display elements and circuit elements, may be disposed in the display area AA, and the gate driver GD and the power supply PS, which are configured to operate the plurality of pixels PX disposed in the display area AA, may be disposed in the non-display area NA.

The pattern layer 120 may be disposed on the lower substrate 111. In the embodiment, the pattern layer 120 may include a plurality of first plate patterns 121 and a plurality of first line patterns 122 disposed in the display area AA, and a plurality of second plate patterns 123 and a plurality of second line patterns 124 disposed in the non-display area NA. For example, the plurality of first plate patterns 121 and the plurality of second plate patterns 123 may be disposed in island shapes spaced apart from one another. The plurality of first line patterns 122 may connect the first plate patterns 121 adjacent to one another, and the plurality of second line patterns 124 may connect the first and second plate patterns 121 and 123 adjacent to one another or connect the plurality of second plate patterns 123 adjacent to one another.

The plurality of pixels PX may be formed on the plurality of first plate patterns 121, and the gate drivers GD and the power supply PS may be formed on the plurality of second plate patterns 123. Meanwhile, FIG. 1 illustrates that the plurality of first plate patterns 121 and the plurality of second plate patterns 123 each have a quadrangular shape. However, the present disclosure is not limited thereto.

The plurality of first line patterns 122 and the plurality of second line patterns 124 may each have a curved shape (e.g., a sinusoidal shape). However, the present disclosure is not limited thereto. The plurality of first line patterns 122 and the plurality of second line patterns 124 may each extend in a zigzag shape or have various shapes such as a shape in which a plurality of rhombic substrates is connected at vertices thereof.

In the embodiment, the plurality of first plate patterns 121, the plurality of first line patterns 122, the plurality of second plate patterns 123, and the plurality of second line patterns 124 are each a rigid pattern. For example, the plurality of first plate patterns 121, the plurality of first line patterns 122, the plurality of second plate patterns 123, and the plurality of second line patterns 124 may be more rigid than the lower substrate 111 and the upper substrate 112. Therefore, the plurality of first plate patterns 121, the plurality of first line patterns 122, the plurality of second plate patterns 123, and the plurality of second line patterns 124 may each have an elastic modulus and hardness higher than an elastic modulus and hardness of the lower substrate 111. For example, the plurality of first plate patterns 121, the plurality of first line patterns 122, the plurality of second plate patterns 123, and the plurality of second line patterns 124 may each have an elastic modulus that may be 1000 or more times higher than the elastic modulus of the lower substrate 111 and the upper substrate 112. However, the present disclosure is not limited thereto.

The plurality of first plate patterns 121, the plurality of first line patterns 122, the plurality of second plate patterns 123, and the plurality of second line patterns 124 may each be made of a plastic material having lower flexibility than those of the lower substrate 111 and the upper substrate 112.

The gate driver GD may supply gate signals to the plurality of pixels PX disposed in the display area AA. The gate driver GD includes a plurality of stages formed on the plurality of second plate patterns 123. The stages of the gate driver GD may be electrically connected to one another through a plurality of gate connection lines. Therefore, the gate signal outputted from any one stage may be transmitted to another stage. The stages may sequentially supply the gate voltages to the plurality of pixels PX respectively connected to the stages.

The power supply PS may be connected to the gate driver GD and supply a gate drive voltage and a gate clock voltage. In addition, the power supply PS may be connected to the plurality of pixels PX and supply pixel drive voltages to the plurality of pixels PX.

A printed circuit board PCB may include a controller, such as an IC chip and a circuit part, a memory, a processor, and/or the like and transmit signals and voltages for operating the display elements to the display elements from a controller. The printed circuit board PCB may include a stretchable area and a non-stretchable area to ensure stretchability. For example, IC chips, circuit parts, memories, processors, and the like may be mounted in the non-stretchable area. Lines electrically connected to the IC chips, the circuit parts, the memories, and the processors may be disposed in the stretchable area.

The data driver DD may supply data voltages to the plurality of pixels PX disposed in the display area AA. The data driver DD may be configured in the form of an IC chip, and thus referred to as a data integrated circuit (D-IC).

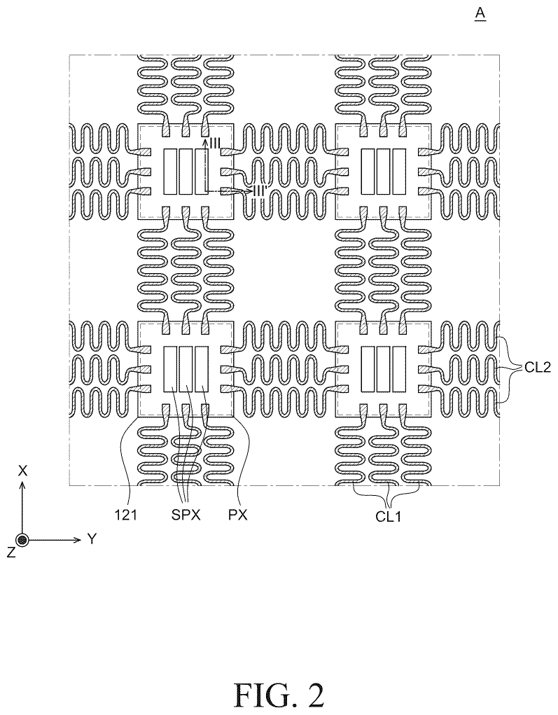

FIG. 2 is an enlarged top plan view illustrating an example of part A in FIG. 1 according to one embodiment of the present disclosure.

FIG. 3 is a cross-sectional view illustrating an example taken along line III-III′ illustrated in FIG. 2 according to one embodiment of the present disclosure.

Meanwhile, FIG. 3 is a cross-sectional view illustrating an example of the display device 100 according to one embodiment of the present disclosure.

With reference to FIGS. 1 to 3, the plurality of first plate patterns 121 may be disposed in the display area AA of the lower substrate 111. The plurality of first plate patterns 121 may be disposed on the lower substrate 111 and spaced apart from one another. For example, as illustrated in FIG. 1, the plurality of first plate patterns 121 may be disposed in a matrix shape on the lower substrate 111. However, the present disclosure is not limited thereto.

The pixel PX including a plurality of subpixels SPX may be disposed on the first plate pattern 121. The plurality of subpixels SPX may each include an LED (or a light-emitting element) 170 that is the display element, and a circuit element, e.g., at least one transistor T configured to operate the LED 170. However, this is provided for illustrative purposes only. In the subpixel SPX, the display element is not limited to the LED but may be changed to an organic light-emitting diode.

The plurality of subpixels SPX may include a red subpixel, a green subpixel, and a blue subpixel. However, the present disclosure is not limited thereto. The colors of the plurality of subpixels SPX may be variously changed, as necessary.

The plurality of subpixels SPX may be connected to a plurality of connection lines CL1 and CL2. That is, the plurality of subpixels SPX may be electrically connected to a first connection line CL1 extending in a first direction X, and the plurality of subpixels SPX may be electrically connected to a second connection line CL2 extending in a second direction Y.

Hereinafter, a cross-sectional structure in the display area AA of the display device 100 according to the embodiment of the present disclosure will be described more specifically with reference to FIG. 3.

First, with reference to FIG. 3, the plurality of first plate patterns 121 may be disposed in the display area AA of the lower substrate 111, and the plurality of first line patterns 122, which connect the first plate patterns 121 adjacent to one another, may be disposed in the display area AA of the lower substrate 111.

According to the embodiment, the display area AA may be divided into a plurality of areas A1 and A2. For example, in an area in which the pattern layer 120 is disposed in the display area AA of the lower substrate 111, an area in which the plurality of first plate patterns 121 are disposed may be defined as a first area A1, and an area in which the plurality of first line patterns 122 are disposed may be defined as a second area A2.

In the embodiment, a first metal layer 131 may be disposed in the first area A1 in which the plurality of first plate patterns 121 are disposed.

The first metal layer 131 may include a protection pattern SLD. The protection pattern SLD may correspond to a part of the first metal layer 131 formed over an upper portion of the first line pattern 122 and a part of the first plate pattern 121 adjacent to the first line pattern 122 in order to suppress damage to the pattern layer 120, e.g., the first line pattern 122 caused by a process of etching a plurality of insulation layers disposed in the second area A2 in which the first line pattern 122 is disposed during a process of manufacturing the display device 100. More specifically, the protection pattern SLD may be formed by removing (e.g., etching) a part of the first metal layer 131 disposed in a part of the first area A1 and disposed in the second area A2 in order to expose the first line pattern 122 after the process of etching the plurality of insulation layers disposed in the second area A2.

According to the embodiment, the protection pattern SLD may be disposed in a partial area of the first area A1 in which the plurality of first plate patterns 121 is disposed. For example, the protection pattern SLD may be disposed to be spaced apart from a boundary between the first area A1 and the second area A2 at a predetermined interval d. In other words, the protection pattern SLD may be formed by not only removing the second area A2 in which the first line pattern 122 is disposed but also removing the first metal layer 131 disposed in an area of the first area A1 adjacent to the boundary between the first area A1 and the second area A2 during the process of removing (e.g., etching) a part of the first metal layer 131.

Meanwhile, because the protection pattern SLD is formed by removing at least a part of the first metal layer 131, the first metal layer 131, e.g., the protection pattern SLD may have an electrically floating state without being in contact with another metal (e.g., electrodes, lines, etc.).

The first metal layer 131 (e.g., the protection pattern SLD) may include a transparent conductive material. For example, the first metal layer 131 (e.g., the protection pattern SLD) may include transparent conductive oxide based on indium tin oxide (ITO), indium zinc oxide (IZO), indium tin zinc oxide (ITZO), zinc oxide (ZnO), and tin oxide (TO). However, the present disclosure is not limited thereto. As described above, because the first metal layer 131, e.g., the protection pattern SLD includes a transparent material, display image quality does not deteriorate even though the first metal layer 131 for protecting the first line pattern 122 is additionally disposed during the process of manufacturing the display device 100.

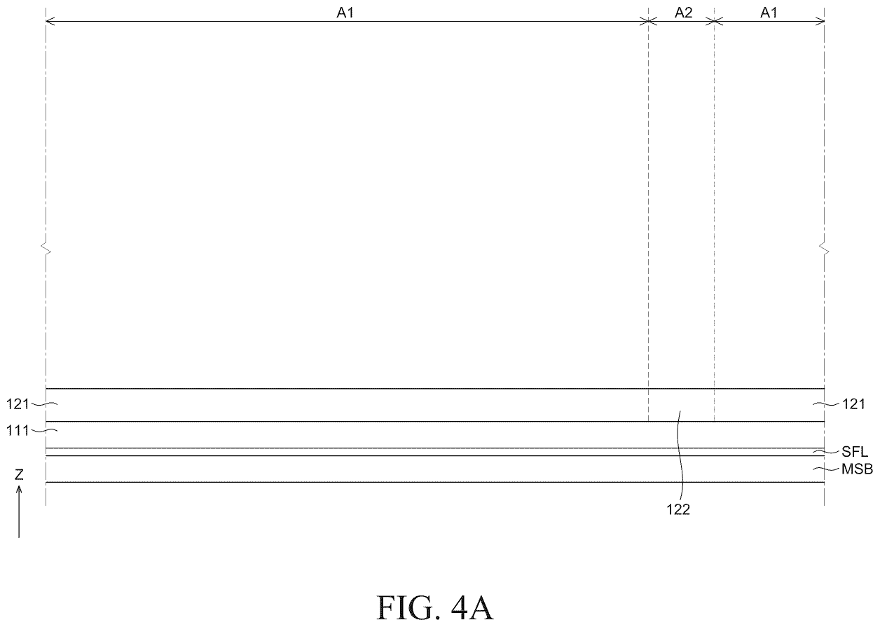

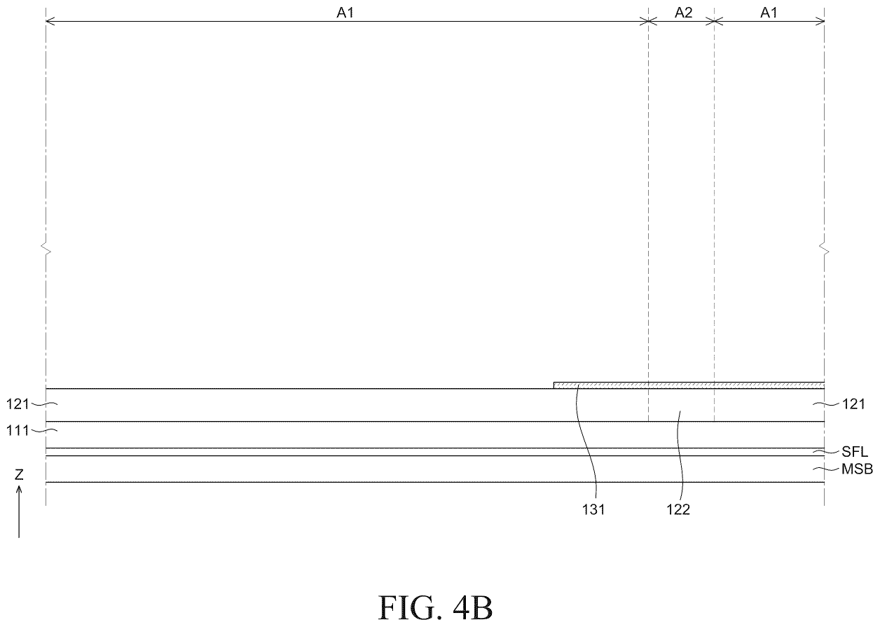

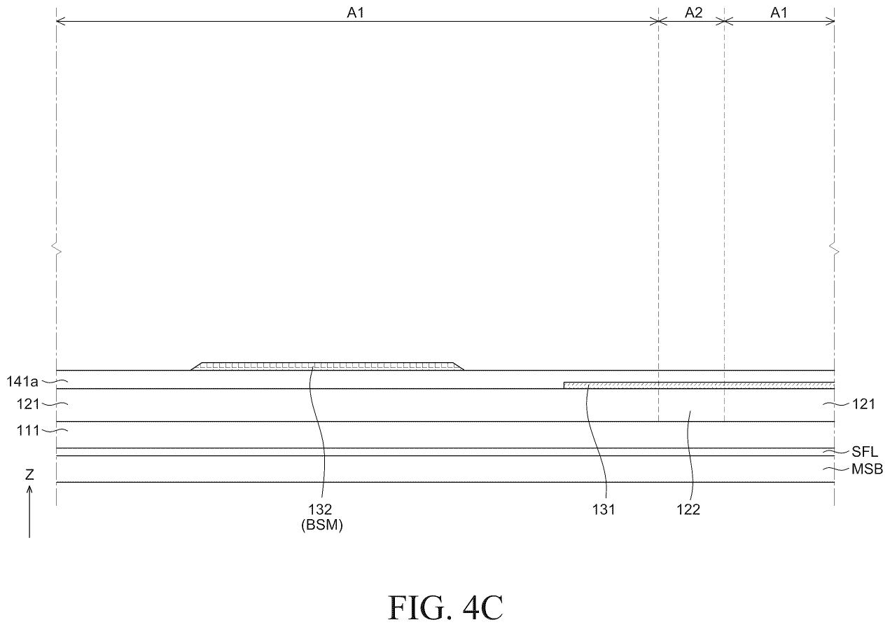

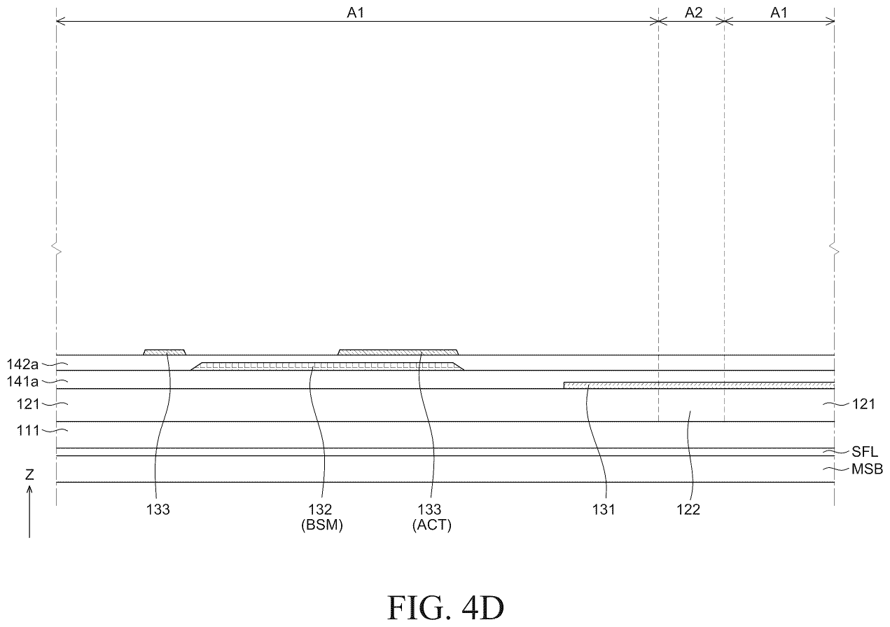

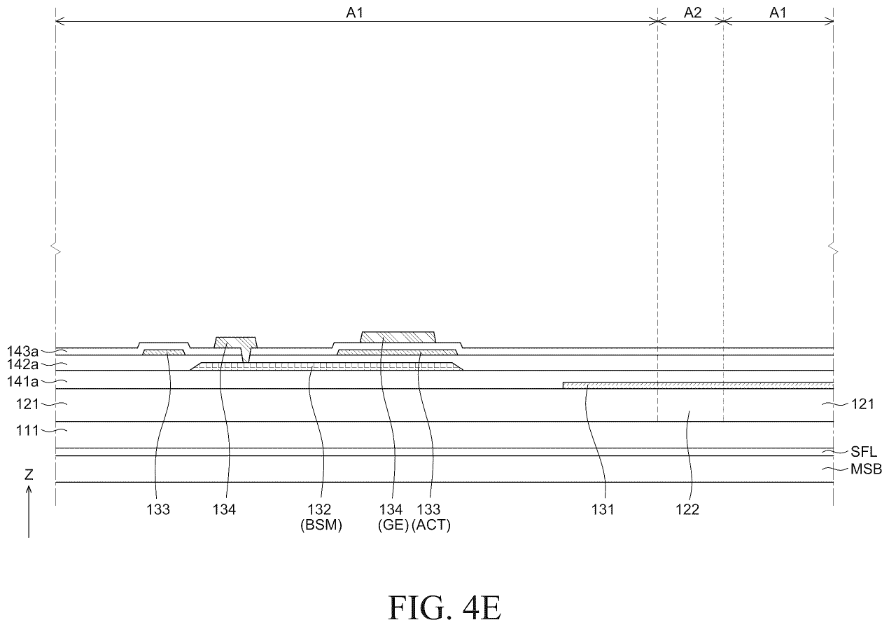

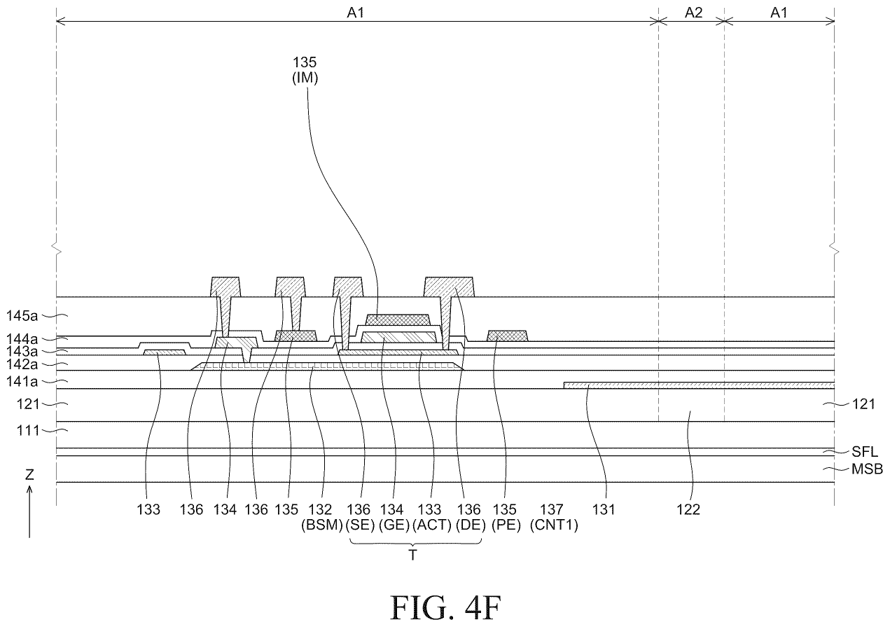

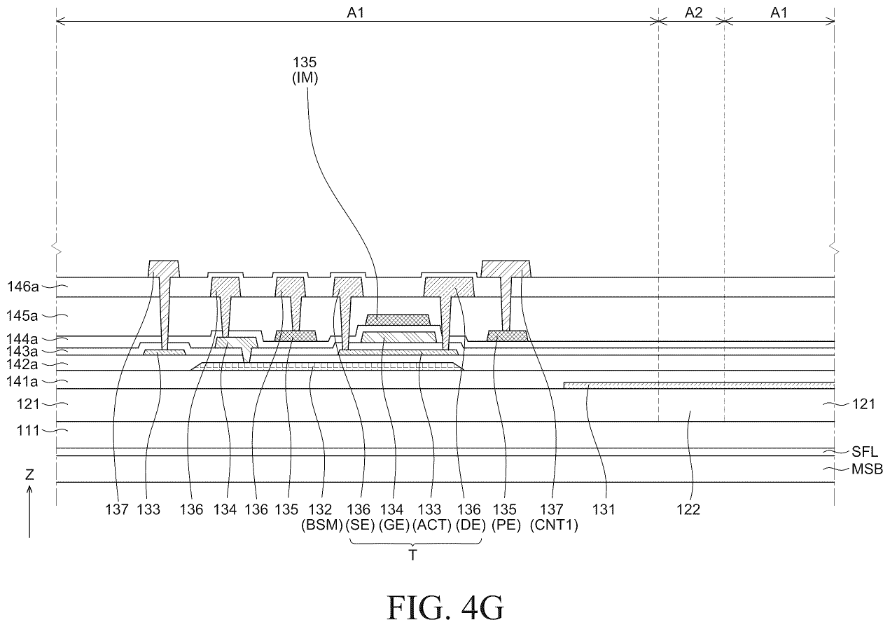

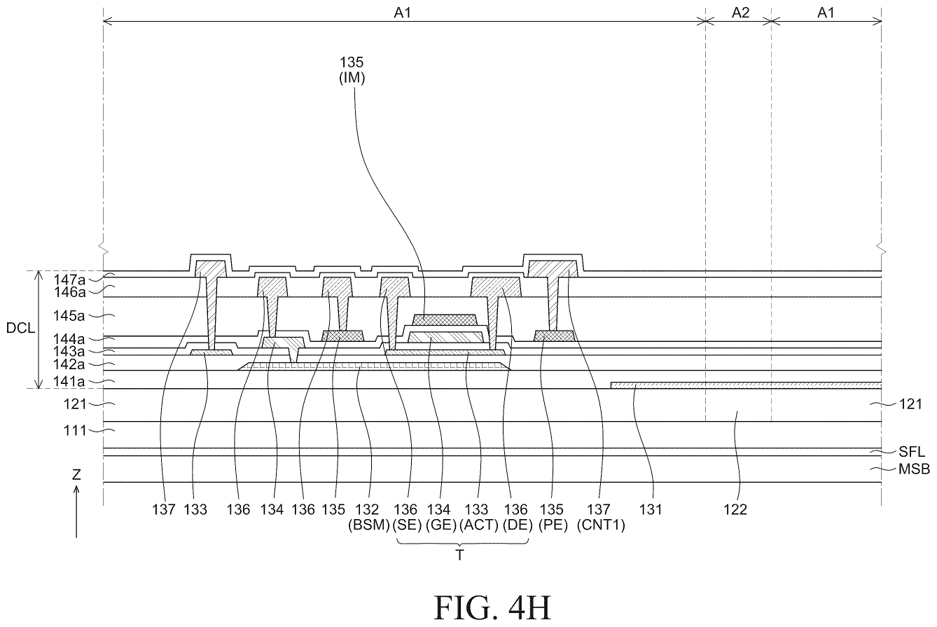

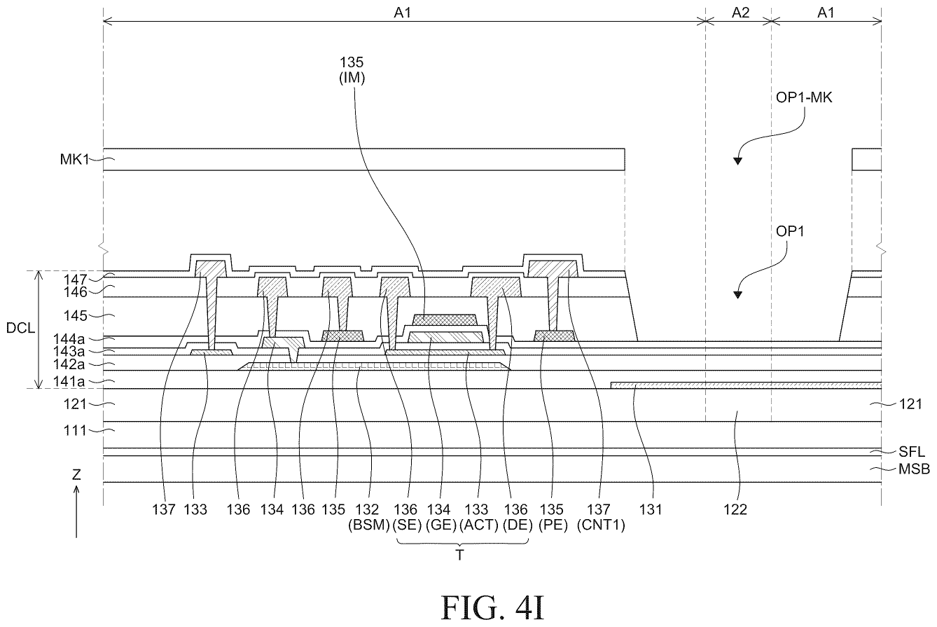

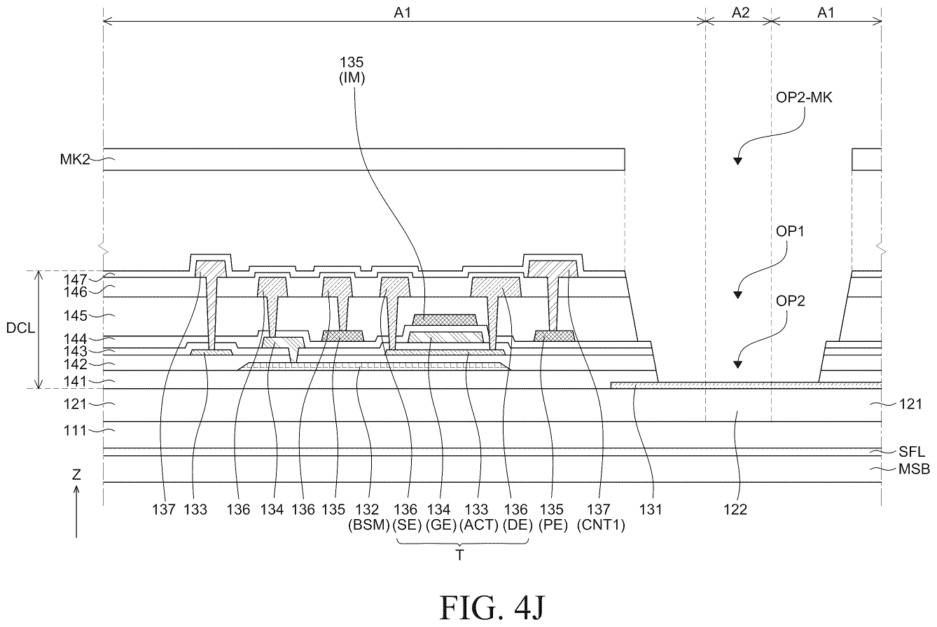

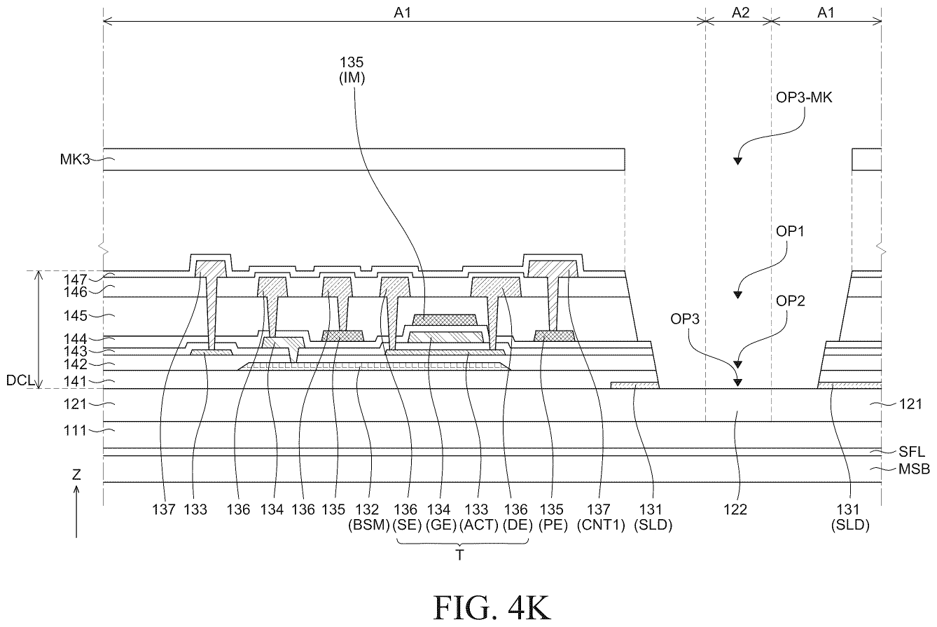

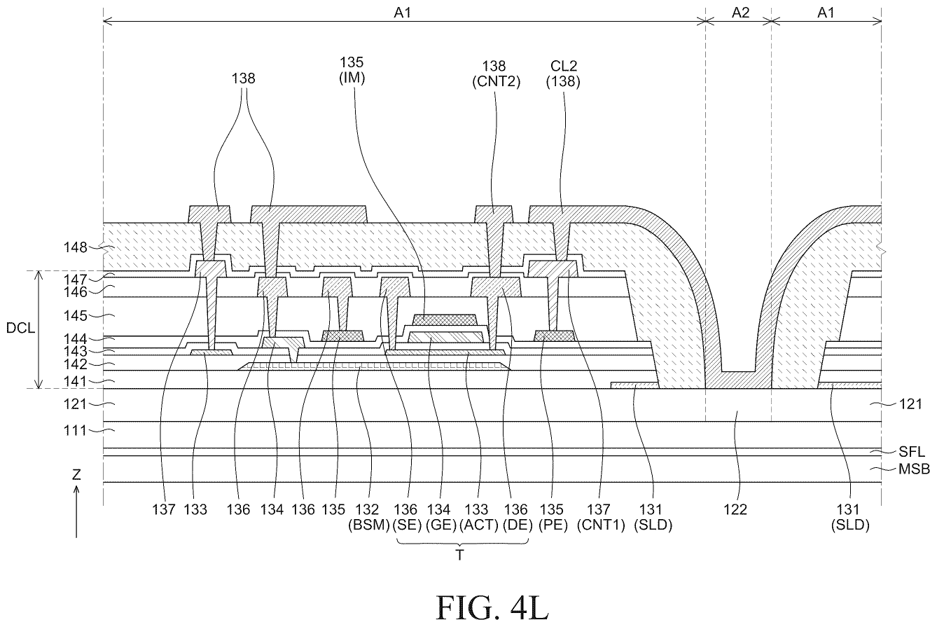

A process of depositing the first metal layer 131 and a process of forming the protection pattern SLD by removing at least a part of the first metal layer 131 will be described more specifically with reference to FIGS. 4A to 4L.

A circuit element layer DCL configured to operate the LED 170, which is the display element, may be disposed in the first area A1 in which the plurality of first plate patterns 121 are disposed. For example, the circuit element layer DCL may be disposed on the plurality of first plate patterns 121 and the first metal layer 131. The circuit element layer DCL may include at least one transistor T configured to operate the LED 170 that is the display element.

The circuit element layer DCL may include a plurality of insulation layers disposed sequentially. For example, the plurality of insulation layers may include a first buffer layer 141 (e.g., main buffer layer or first insulation layer), a second buffer layer 142 (e.g., active buffer layer or second insulation layer), a gate insulation layer 143 (or third insulation layer), a first interlayer insulation layer 144 (or fourth insulation layer), a second interlayer insulation layer 145 (or fifth insulation layer), a third interlayer insulation layer 146 (or sixth insulation layer), and a passivation layer 147 (or seventh insulation layer). However, the present disclosure is not limited thereto. In addition to the above-mentioned insulation layers, various insulation layers may be additionally disposed on the plurality of first plate patterns 121, or at least one of the first buffer layer 141, the second buffer layer 142, the gate insulation layer 143, the first interlayer insulation layer 144, the second interlayer insulation layer 145, the third interlayer insulation layer 146, or the passivation layer 147 may be excluded.

According to the embodiment, the plurality of insulation layers disposed on the plurality of first plate patterns 121 may be disposed in a partial area of the first area A1 in which the plurality of first plate patterns 121 are disposed. For example, the first buffer layer 141, which is disposed at a lowermost end among the plurality of insulation layers disposed on the plurality of first plate patterns 121, may be disposed to be spaced apart from the boundary between the first area A1 and the second area A2 at the predetermined interval d. For example, an end of the first buffer layer 141 and an end the protection pattern SLD may overlap.

Meanwhile, a planarization layer 148 to be described below may be disposed in an area of the first area A1 in which the plurality of insulation layers disposed on the plurality of first plate patterns 121 are not disposed (e.g., an area of the first buffer layer 141 disposed to be spaced apart from the boundary between the first area A1 and the second area A2 at the predetermined interval d).

At least one metal layer and at least one semiconductor layer, which constitute the circuit element (e.g., the transistor T) for operating the LED 170, may be included between the plurality of first plate patterns 121 and the plurality of insulation layers disposed on the plurality of first plate patterns 121. For example, at least one metal layer and at least one semiconductor layer may include a second metal layer 132, a semiconductor layer 133, a third metal layer 134, a fourth metal layer 135, a fifth metal layer 136, and a sixth metal layer 137. However, the present disclosure is not limited thereto. In addition to the above-mentioned metal layer and the above-mentioned semiconductor layer, various metal layers and various semiconductor layers may be additionally disposed on the plurality of first plate patterns 121, or at least one of the second metal layer 132, the semiconductor layer 133, the third metal layer 134, the fourth metal layer 135, the fifth metal layer 136, or the sixth metal layer 137 may be excluded.

More specifically, the first buffer layer 141 (e.g., main buffer layer) may be disposed on the first plate pattern 121. For example, the first buffer layer 141 may be disposed on the first plate pattern 121 and cover the first metal layer 131 (e.g., the protection pattern SLD).

The first buffer layer 141 may include an insulating material and be formed on the plurality of first plate patterns 121 in order to protect various constituent elements of the display device 100 from permeation of moisture (H₂O) and oxygen (O₂) from the outside of the lower substrate 111 and the plurality of first plate patterns 121. The first buffer layer 141 may be excluded in accordance with the structure or properties of the display device 100.

In one embodiment, the first buffer layer 141 may be formed in an area in which the lower substrate 111 overlaps the plurality of first plate patterns 121 and the plurality of second plate patterns 123. As described above, because the first buffer layer 141 may be made of an inorganic material, the display device 100 may be easily damaged or cracked during a process of stretching the display device 100. Therefore, the first buffer layer 141 may be formed on upper portions of the plurality of first plate patterns 121 and upper portions of the plurality of second plate patterns 123 by being patterned in shapes of the plurality of first plate patterns 121 and shapes of the plurality of second plate patterns 123 without being formed in an area between the plurality of first plate patterns 121 and the plurality of second plate patterns 123. Therefore, in the case of the display device 100 according to the embodiment of the present disclosure, the first buffer layer 141 is formed in the area that overlaps the plurality of first plate patterns 121 and the plurality of second plate patterns 123 that are rigid patterns. Therefore, it is possible to suppress damage to various constituent elements of the display device 100 even though the display device 100 is deformed by being curved or stretched. For example, as described above, the first buffer layer 141 may be disposed in and overlap at least a partial area of the first area A1 without being disposed in the second area A2 in which the first line pattern 122 is disposed. For example, the first buffer layer 141 may not be disposed in an area of the first area A1 corresponding to the portion spaced apart from the boundary between the first area A1 and the second area A2 at the predetermined interval d.

The second metal layer 132 may be disposed on the first buffer layer 141. The second metal layer 132 may include various metallic materials. In the embodiment, the second metal layer 132 may include a barrier layer (barrier shield metal (BSM)) and be disposed on the plurality of first plate patterns 121.

The barrier layer BSM may protect at least a part of the semiconductor layer 133, e.g., an active layer ACT of the transistor T. For example, the barrier layer BSM may be disposed on the first buffer layer 141 and overlap the active layer ACT of the transistor T. In addition, in a cross-sectional view, the barrier layer BSM may have a width equal to or larger than a width of the active layer ACT. However, the present disclosure is not limited thereto.

Meanwhile, as illustrated in FIG. 3, the second metal layer 132, e.g., the barrier layer BSM may be connected to another metal layer (e.g., the third metal layer 134 or the fifth metal layer 136) and receive a constant voltage. However, the present disclosure is not limited thereto. The barrier layer BSM may be in a floating state in which no voltage is applied.

The second buffer layer 142 (e.g., active buffer layer) may be disposed on the first buffer layer 141. For example, the second buffer layer 142 may be disposed on the first buffer layer 141 and cover the second metal layer 132.

The second buffer layer 142 may include an insulating material and insulate the second metal layer 132 (e.g., the barrier layer BSM) and the active layer ACT of the transistor T.

At least one transistor T including a gate electrode GE, the active layer ACT, a source electrode SE, and a drain electrode DE may be disposed on the second buffer layer 142. However, the present disclosure is not limited thereto. According to the embodiment, at least one transistor T may also be defined as further including the barrier layer BSM.

The semiconductor layer 133 may be disposed on the second buffer layer 142. The semiconductor layer 133 may include the active layer ACT of the transistor T.

The gate insulation layer 143 may be disposed on the second buffer layer 142. For example, the gate insulation layer 143 may include an insulating material and be disposed on the second buffer layer 142 to cover the semiconductor layer 133. The gate insulation layer 143 may electrically insulate the gate electrode GE and the active layer ACT of the transistor T.

The third metal layer 134 may be disposed on the gate insulation layer 143. The third metal layer 134 may include various metallic materials. The third metal layer 134 may include the gate electrode GE of the transistor T. Therefore, the gate electrode GE of the transistor T may be insulated from the active layer ACT by the gate insulation layer 143. In addition, the gate electrode GE of the transistor T may overlap the active layer ACT.

The first interlayer insulation layer 144 may be disposed on the gate insulation layer 143. For example, the first interlayer insulation layer 144 may be disposed on the gate insulation layer 143 and cover the third metal layer 134.

The first interlayer insulation layer 144 may include an insulating material and insulate the third metal layer 134 (e.g., the gate electrode GE of the transistor T) and the fourth metal layer 135. The fourth metal layer 135 may be disposed on the first interlayer insulation layer 144. The fourth metal layer 135 may include various metallic materials. The fourth metal layer 135 may include an intermediate metal layer IM and a pad electrode PE.

The intermediate metal layer IM may overlap the gate electrode GE of the transistor T. Therefore, a capacitor may be formed in an area in which the intermediate metal layer IM and the gate electrode GE of the transistor T overlap each other. For example, in case that the transistor T is a driving transistor, the gate electrode GE included in the third metal layer 134, the first interlayer insulation layer 144, and the intermediate metal layer IM included in the fourth metal layer 135 may form a storage capacitor. However, the arrangement area of the intermediate metal layer IM is not limited thereto. The capacitor may be formed as the intermediate metal layer IM overlaps another electrode.

The pad electrode PE may provide various signals and/or voltages. For example, the pad electrode PE may constitute at least one of a data pad configured to transmit a data voltage to the plurality of subpixels SPX, a gate pad configured to transmit a gate signal to the plurality of subpixels SPX, or a voltage pad configured to transmit a pixel drive voltage to the plurality of subpixels SPX. To this end, the pad electrode PE may be electrically connected to the connection lines CL1 (not shown in FIG. 3) and CL2, which are included in a seventh metal layer 138, via a first connection pad CNT1, which is included in the sixth metal layer 137, through at least one contact hole. Therefore, the data voltage, the gate signal, and/or the pixel drive voltage supplied through the connection lines CL1 and CL2 may be transmitted to the pad electrode PE and provided to the subpixel SPX.

The second interlayer insulation layer 145 may be disposed on the first interlayer insulation layer 144. For example, the second interlayer insulation layer 145 may be disposed on the first interlayer insulation layer 144 and cover the fourth metal layer 135.

The second interlayer insulation layer 145 may include an insulating material and insulate the fourth metal layer 135 (e.g., the intermediate metal layer IM and the pad electrode PE) and the fifth metal layer 136 (e.g., the source electrode SE and the drain electrode DE of the transistor T). The fifth metal layer 136 may be disposed on the second interlayer insulation layer 145. The fifth metal layer 136 may include various metallic materials. The fifth metal layer 136 may include the source electrode SE and the drain electrode DE of the transistor T. The source electrode SE and the drain electrode DE of the transistor T may be disposed on the same layer and spaced apart from each other.

The source electrode SE and the drain electrode DE of the transistor T may be electrically connected to the active layer ACT while adjoining the active layer ACT. The third interlayer insulation layer 146 may be disposed on the second interlayer insulation layer 145. For example, the third interlayer insulation layer 146 may be disposed on the second interlayer insulation layer 145 and cover the fifth metal layer 136.

The third interlayer insulation layer 146 may include an insulating material and insulate the fifth metal layer 136 (e.g., the source electrode SE and the drain electrode DE of the transistor T) and the sixth metal layer 137 (e.g., the first connection pad CNT1). The sixth metal layer 137 may be disposed on the third interlayer insulation layer 146. The sixth metal layer 137 may include various metallic materials. The sixth metal layer 137 may include the first connection pad CNT1. The first connection pad CNT1 may be electrically connected to the pad electrode PE through a contact hole and electrically connected to the connection lines CL1 and CL2 through another contact hole. Therefore, as described above, the data voltage, the gate signal, and/or the pixel drive voltage supplied through the connection lines CL1 and CL2 may be transmitted to the pad electrode PE and provided to the subpixel SPX. The passivation layer 147 may be disposed on the third interlayer insulation layer 146. For example, the passivation layer 147 may be disposed on the third interlayer insulation layer 146 and cover the sixth metal layer 137.

The passivation layer 147 may include an insulating material. The passivation layer 147 may be disposed to cover various metal layers disposed below the passivation layer 147 and protect various constituent elements, e.g., the transistor T and the like disposed below the passivation layer 147 from permeation of moisture, oxygen, and the like.

Meanwhile, the second buffer layer 142, the gate insulation layer 143, the first interlayer insulation layer 144, the second interlayer insulation layer 145, the third interlayer insulation layer 146, and the passivation layer 147 may be patterned and formed only in an area that overlaps the plurality of first plate patterns 121 (e.g., the first area A1). For example, the second buffer layer 142, the gate insulation layer 143, the first interlayer insulation layer 144, the second interlayer insulation layer 145, the third interlayer insulation layer 146, and the passivation layer 147 may each be made of an inorganic material, like the first buffer layer 141. For this reason, the display device 100 may be easily cracked and damaged during the process of stretching the display device 100. Therefore, the second buffer layer 142, the gate insulation layer 143, the first interlayer insulation layer 144, the second interlayer insulation layer 145, the third interlayer insulation layer 146, and the passivation layer 147 may be formed above the plurality of first plate patterns 121 by being patterned in the shapes of the plurality of first plate patterns 121 without being formed in the area between the plurality of first plate patterns 121. For example, the second buffer layer 142, the gate insulation layer 143, the first interlayer insulation layer 144, the second interlayer insulation layer 145, the third interlayer insulation layer 146, and the passivation layer 147 may be disposed in and overlap at least a partial area of the first area A1 without being disposed in the second area A2 in which the first line pattern 122 is disposed. For example, the second buffer layer 142, the gate insulation layer 143, the first interlayer insulation layer 144, the second interlayer insulation layer 145, the third interlayer insulation layer 146, and the passivation layer 147 may not be disposed in the area of the first area A1 corresponding to the portion spaced apart from the boundary between the first area A1 and the second area A2 at the predetermined interval d.

The planarization layer 148 may be disposed on the circuit element layer DCL. For example, the planarization layer 148 may be formed on the passivation layer 147. The planarization layer 148 may be disposed between the circuit element layer DCL (e.g., the passivation layer 147) and the LED 170.

The planarization layer 148 may planarize an upper portion of the circuit element layer DCL. For example, the planarization layer 148 may planarize an upper portion of at least one transistor T included in the circuit element layer DCL. The planarization layer 148 may be configured as a single layer or a plurality of layers and made of an organic material.

In the embodiment, with reference to FIG. 3, the planarization layer 148 may be disposed to cover an top surface of the insulation layer, which is disposed on the uppermost portion among the plurality of insulation layers included in the circuit element layer DCL on the plurality of first plate patterns 121, a side surface of each of the plurality of insulation layers, and a part of a top surface of the first plate pattern 121. For example, the planarization layer 148 may be disposed to cover the top and side surfaces of the first buffer layer 141, the second buffer layer 142, the gate insulation layer 143, the first interlayer insulation layer 144, the second interlayer insulation layer 145, the third interlayer insulation layer 146, and the passivation layer 147 on the plurality of first plate patterns 121. Further, the planarization layer 148 may be disposed to surround the first buffer layer 141, the second buffer layer 142, the gate insulation layer 143, the first interlayer insulation layer 144, the second interlayer insulation layer 145, the third interlayer insulation layer 146, and the passivation layer 147 together with the plurality of first plate patterns 121. Specifically, the planarization layer 148 may be disposed to cover top and side surfaces of the passivation layer 147, a side surface of the third interlayer insulation layer 146, a side surface of the second interlayer insulation layer 145, a side surface of the first interlayer insulation layer 144, a side surface of the gate insulation layer 143, a side surface of the second buffer layer 142, a side surface of the first buffer layer 141, and a part of top surfaces of the plurality of first plate patterns 121. For example, the planarization layer 148 may be disposed to cover a portion corresponding to an area of the top surfaces of the plurality of first plate patterns 121 spaced apart from the boundary between the first area A1 and the second area A2 at the predetermined interval d.

Therefore, the planarization layer 148 may compensate for level differences between the side surfaces of the first buffer layer 141, the second buffer layer 142, the gate insulation layer 143, the first interlayer insulation layer 144, the second interlayer insulation layer 145, the third interlayer insulation layer 146, and the passivation layer 147. Further, the planarization layer 148 may increase bonding strength with the connection lines CL1 and CL2 disposed on the side surface of the planarization layer 148.

With reference to FIG. 3, an inclination angle of the side surface of the planarization layer 148 may be smaller than inclination angles defined by the side surfaces of the first buffer layer 141, the second buffer layer 142, the gate insulation layer 143, the first interlayer insulation layer 144, the second interlayer insulation layer 145, the third interlayer insulation layer 146, and the passivation layer 147. For example, the side surface of the planarization layer 148 may have an inclination more gradual than inclinations defined by the side surface of the passivation layer 147, the side surface of the third interlayer insulation layer 146, the side surface of the second interlayer insulation layer 145, the side surface of the first interlayer insulation layer 144, the side surface of the gate insulation layer 143, the side surface of the second buffer layer 142, and the side surface of the first buffer layer 141. Therefore, the connection lines CL1 and CL2 disposed to adjoin the side surface of the planarization layer 148 is disposed to have a gradual inclination, such that stress applied to the connection lines CL1 and CL2 may be reduced when the display device 100 is stretched. Further, the side surface of the planarization layer 148 may have a relatively gradual inclination, thereby inhibiting the connection lines CL1 and CL2 from cracking or separating from the side surface of the planarization layer 148.

With reference to FIGS. 2 and 3, the seventh metal layer 138 may be disposed on the planarization layer 148. The seventh metal layer 138 may include the plurality of connection lines CL1 and CL2 and a second connection pad CNT2.

The connection lines CL1 and CL2 may be connected to the circuit element layer DCL. For example, the connection lines CL1 and CL2 may electrically connect the pad (e.g., the pad electrode PE) on the plurality of first plate patterns 121.

The connection lines CL1 and CL2 may be disposed on the plurality of first line patterns 122. Further, the connection lines CL1 and CL2 may extend even on the plurality of first plate patterns 121 so as to be electrically connected to the pad electrode PE on the plurality of first plate patterns 121. For example, the connection lines CL1 and CL2 may be connected to the side and top surfaces of the planarization layer 148 for each of the plurality of first line patterns 122. Meanwhile, the first line pattern 122 may not be disposed in an area in which the connection lines CL1 and CL2 are not disposed among the areas between the plurality of first plate patterns 121.

The connection lines CL1 and CL2 may include the first connection line CL1 and the second connection line CL2. The first connection line CL1 and the second connection line CL2 may be disposed between the plurality of first plate patterns 121. The first connection line CL1 and the second connection line CL2 may each include a metallic material.

More specifically, as illustrated in FIG. 2, the first connection line CL1 may refer to a line extending in the first direction X between the plurality of first plate patterns 121 among the connection lines CL1 and CL2, and the second connection line CL2 may refer to a line extending in the second direction Y between the plurality of first plate patterns 121 among the connection lines CL1 and CL2.

Meanwhile, in the case of a general display device, various lines such as a plurality of gate lines and a plurality of data lines are disposed between a plurality of subpixels and extend in straight shapes. The plurality of subpixels is connected to the single signal line. Therefore, in the case of the general display device, various lines such as the gate line, the data line, the high-potential voltage line, and the reference voltage line extend in a direction from one side to the other side without interruption on the substrate.

In contrast, in the case of the display device 100 according to the embodiment of the present disclosure, various lines such as gate lines, data lines, high-potential voltage lines, reference voltage lines, and initialization voltage lines, which are straight lines that may be considered as being used for the general display panel of the display device, may be disposed only on the plurality of first plate patterns 121 and the plurality of second plate patterns 123. That is, in the display device 100 according to the embodiment of the present disclosure, the straight lines may be disposed only on the plurality of first plate patterns 121 and the plurality of second plate patterns 123.

In the display device 100 according to the embodiment of the present disclosure, the pads (e.g., the pad electrodes PE) on the two adjacent first plate patterns 121 may be connected by the plurality of connection lines CL1 and CL2. Therefore, the connection lines CL1 and CL2 may electrically connect the pad electrodes PE on the two adjacent first plate patterns 121. Therefore, the display device 100 according to the embodiment of the present disclosure may include the plurality of connection lines CL1 and CL2 to electrically connect various lines such as the gate lines, the data lines, the high-potential voltage lines, and the reference voltage lines between the plurality of first plate patterns 121.

For example, the gate line may be disposed on the plurality of first plate patterns 121 disposed adjacent to one another in the first direction X, and the gate pads included in the pad electrodes PE may be disposed at two opposite ends of the gate line. In this case, the plurality of gate pads on the plurality of first plate patterns 121 disposed adjacent to one another in the first direction X may be connected to one another by the first connection line CL1 that serves as a gate line. Therefore, the gate line, which is disposed on the plurality of first plate patterns 121, and the first connection line CL1, which is disposed on the first line pattern 122, may serve as a single gate line. The gate line may be referred to as a scan signal line. In addition, among all the various lines that may be included in the display device 100, the line extending in the first direction X, for example, the light-emitting signal line, the low-potential voltage line, and the high-potential voltage line may also be electrically connected by the first connection line CL1, as described above.

In addition, the second connection line CL2 may connect the data pads on the two first plate patterns 121 disposed side by side, among the pad electrodes PE, e.g., the data pads on the plurality of first plate patterns 121 disposed adjacent to one another in the second direction Y. The second connection line CL2 may serve as the data line, the high-potential voltage line, the low-potential voltage line, or the reference voltage line. However, the present disclosure is not limited thereto. Internal lines on the plurality of first plate patterns 121 disposed in the second direction Y may be connected by the plurality of second connection lines CL2 that serves as the data lines, such that the single data voltage may be transmitted.

As illustrated in FIG. 3, the connection lines CL1 and CL2 may be disposed to adjoin the top and side surfaces of the planarization layer 148 disposed on the first plate pattern 121. Further, the connection lines CL1 and CL2 may extend to the top surface of the first line pattern 122. For example, the connection lines CL1 and CL2 may be disposed to directly adjoin the top surface of the first line pattern 122. For example, because the first metal layer 131 disposed on the first line pattern 122 is removed (e.g., etched) before the process of depositing the connection lines CL1 and CL2, i.e., the seventh metal layer 138, the top surface of the first line pattern 122 is exposed in the process step of depositing the seventh metal layer 138. Therefore, the connection lines CL1 and CL2 included in the seventh metal layer 138 may be deposited to be in direct contact with the top surface of the first line pattern 122.

However, although not separately illustrated in FIG. 3, because a rigid pattern need not be disposed in the area in which the first connection line CL1 and the second connection line CL2 are not disposed, the first line pattern 122, which is a rigid pattern, is not disposed below the first connection line CL1 and the second connection line CL2.

With reference to FIG. 3, a bank 149 may be formed on the seventh metal layer 138, e.g., the second connection pad CNT2, the connection lines CL1 and CL2, and the planarization layer 148. The bank 149 may include an insulating material and separate the adjacent subpixels SPX. The bank 149 may be disposed to at least partially cover the connection lines CL1 and CL2 and the planarization layer 148.

Meanwhile, FIG. 3 illustrates that a height of the bank 149 is lower than a height of the LED 170. However, the present disclosure is not limited thereto. The height of the bank 149 may be equal to the height of the LED 170.

With reference to FIG. 3, the LED 170 may be disposed on the circuit element layer DCL. For example, the LED 170 may be disposed on the seventh metal layer 138, e.g., the second connection pad CNT2 and the connection lines CL1 and CL2. The LED 170 may include an n-type layer 171, an active layer 172, a p-type layer 173, an n-electrode 174, and a p-electrode 175. The LED 170 of the display device 100 according to the embodiment of the present disclosure may have a flip-chip structure having the n-electrode 174 and the p-electrode 175 formed on one surface thereof. However, this is provided for illustrative purposes only, and the structure of the LED 170 is not limited thereto. The LED 170 may be variously modified and carried out.

According to the embodiment, the n-type layer 171 may also be disposed on a separate base substrate made of a material capable of emitting light.

The active layer 172 may be disposed on the n-type layer 171. The active layer 172 may be a light-emitting layer provided in the LED 170 and configured to emit light. The p-type layer 173 may be disposed on the active layer 172.

As described above, the LED 170 according to the embodiment of the present disclosure may be manufactured by sequentially stacking the n-type layer 171, the active layer 172, and the p-type layer 173, etching a predetermined portion, and then forming the n-electrode 174 and the p-electrode 175. In this case, the predetermined portion may be a space for spacing the n-electrode 174 and the p-electrode 175. The predetermined portion may be etched so that a part of the n-type layer 171 is exposed. In other words, a surface of the LED 170, on which the n-electrode 174 and the p-electrode 175 are to be disposed, may be a surface having different height levels instead of a planarized surface.

The n-electrode 174 may be disposed in the area etched as described above. The n-electrode 174 may be made of an electrically conductive material. Further, the p-electrode 175 may be disposed in a non-etched area. The p-electrode 175 may also be made of an electrically conductive material. For example, the n-electrode 174 may be disposed on the n-type layer 171 exposed by the etching process, and the p-electrode 175 may be disposed on the p-type layer 173. The p-electrode 175 may be made of the same material as the n-electrode 174.

A bonding layer AD may be disposed on the second connection pad CNT2, such that the LED 170 may be bonded onto the second connection pad CNT2.

The bonding layer AD may be a conductive bonding layer made by dispersing conductive balls into an insulating base member. Therefore, in case that heat or pressure is applied to the bonding layer AD, the conductive balls are electrically connected in a portion to which heat or pressure is applied, such that the bonding layer AD has conductive properties. An area, which is not pressed, may have insulation properties. It is possible to electrically connect the second connection pad CNT2 and the LED 170 by applying the bonding layer AD onto the second connection pad CNT2 in an inkjet manner or the like, transferring the LED 170 onto the bonding layer AD, and pressing and heating the LED 170. However, the other portion of the bonding layer AD, except for a portion of the bonding layer AD disposed between the LED 170 and the second connection pad CNT2, may have insulation properties.

Further, the second connection pad CNT2 may be electrically connected to the drain electrode DE of the transistor T and receive the drive voltage, which is used to operate the LED 170, from the transistor T. FIG. 3 illustrates that the second connection pad CNT2 and the drain electrode DE of the transistor T are connected by being in direct contact with each other. However, the present disclosure is not limited thereto. The second connection pad CNT2 and the drain electrode DE of the transistor T may be connected indirectly through another constituent element.

The upper substrate 112 may be a substrate configured to support various constituent elements disposed below the upper substrate 112. Specifically, the upper substrate 112 may be formed by coating the lower substrate 111 and the first plate pattern 121 with a material, which constitutes the upper substrate 112, and curing the material. The upper substrate 112 may be disposed to adjoin the lower substrate 111, the first plate pattern 121, the first line pattern 122, and the connection lines CL1 and CL2.

Meanwhile, although not illustrated in FIG. 3, a polarizing layer may be disposed on the upper substrate 112. The polarizing layer may serve to polarize light entering from the outside of the display device 100 and reduce reflection of external light. In addition, other optical films and the like other than the polarizing layer may be disposed on the upper substrate 112.

In addition, a filling layer 190 may be disposed on the front surface of the lower substrate 111 and fill portions between the constituent elements disposed on the upper substrate 112 and the lower substrate 111. The filling layer 190 may be made of a curable bonding agent. Specifically, the filling layer 190 may be formed by coating the front surface of the lower substrate 111 with a material, which constitutes the filling layer 190, and curing the material. The filling layer 190 may be disposed between the constituent elements disposed on the upper substrate 112 and the lower substrate 111.

FIGS. 4A to 4L are process diagrams illustrating a method of manufacturing the display device according to the embodiments of the present disclosure.

Meanwhile, FIGS. 4A to 4L are cross-sectional views of a process of manufacturing the display device 100 according to the embodiment of the present disclosure described with reference to FIG. 3. For example, FIGS. 4A to 4L sequentially illustrate the method of manufacturing the display device 100 according to the embodiment of the present disclosure described with reference to FIG. 3.

Meanwhile, for convenience of description, the contents, which are identical to the contents described with reference to FIGS. 1 and 3, will not be described repeatedly.

Meanwhile, the insulation layer, the semiconductor layer, and the metal layer described with reference to FIGS. 4A to 4L may be formed by a typical process of manufacturing a circuit element by forming various types of electrodes, various types of patterns, signal lines, and the like by forming an insulation layer, a semiconductor layer, and a metal layer by coating, deposition, and the like and selectively patterning the insulation layer, the semiconductor layer, and the metal layer by photolithography and etching processes. Therefore, for convenience of description, a specific description of the method will be omitted.

First, with reference to FIG. 4A, a sacrificial layer SFL may be formed on a mother substrate MSB.

The mother substrate MSB is a substrate for supporting the constituent elements disposed on the lower substrate 111 during the process of manufacturing the display device 100. The mother substrate MSB may be made of a material having rigidity. For example, the mother substrate MSB may be made of glass. However, the present disclosure is not limited thereto.

The mother substrate MSB may be used to simultaneously manufacture the plurality of display devices 100. For example, a plurality of cells may be defined on the mother substrate MSB, and the cells may respectively correspond to the plurality of display devices to be manufactured.

The sacrificial layer SFL formed on the mother substrate MSB is a layer used to separate the lower substrate 111 of the display device 100 from the mother substrate MSB. The sacrificial layer SFL may be made of a material that decomposes an interfacial coupling force when irradiated with laser beams to decrease a bonding force with the lower substrate 111 of the display device 100. The sacrificial layer SFL may be formed by depositing silicon nitride and silicon oxide onto an entire surface of the mother substrate MSB. However, the present disclosure is not limited thereto.

Thereafter, the lower substrate 111 may be provided on the sacrificial layer SFL. As described with reference to FIG. 3, the lower substrate 111 may be divided into the first area A1 and the second area A2.

Thereafter, the pattern layer 120 may be provided on the lower substrate 111. For example, the pattern layer 120 may be provided on the lower substrate 111 and include the first plate pattern 121 configured to overlap the first area A1 of the lower substrate 111, and the first line pattern 122 configured to overlap the second area A2 of the lower substrate 111.

Thereafter, with reference further to FIG. 4B, the first metal layer 131 may be provided on the pattern layer 120. For example, the first metal layer 131 may be provided on the pattern layer 120 and provided in a partial area of the first area A1 and the second area A2.

Thereafter, first to seventh insulating materials 141a, 142a, 143a, 144a, 145a, 146a, and 147a may be sequentially provided on the pattern layer 120 and the first metal layer 131.

More specifically, first, with reference further to FIG. 4C, the first insulating material 141a may be provided on the first metal layer 131. For example, the first insulating material 141a may be provided on the first plate pattern 121 and cover the first metal layer 131. The first insulating material 141a may be formed over the first area A1 and the second area A2 of the lower substrate 111.

The first insulating material 141a may be a material for forming the first buffer layer 141 described with reference to FIG. 3.

In addition, the second metal layer 132 may be provided on the first insulating material 141a. In one embodiment, the barrier layer BSM may be formed by applying and depositing the second metal layer 132 onto the first insulating material 141a and then patterning at least a part of the second metal layer 132.

Thereafter, with reference further to FIG. 4D, the second insulating material 142a may be provided on the second metal layer 132. For example, the second insulating material 142a may be provided on the first insulating material 141a and cover the second metal layer 132. The second insulating material 142a may be formed over the first area A1 and the second area A2 of the lower substrate 111.

The second insulating material 142a may be a material for forming the second buffer layer 142 described with reference to FIG. 3.

In addition, the semiconductor layer 133 may be provided on the second insulating material 142a. In the embodiment, the active layer ACT of the transistor T may be formed by depositing the semiconductor layer 133 onto the second insulating material 142a and then patterning at least a part of the semiconductor layer 133.

Thereafter, with reference further to FIG. 4E, the third insulating material 143a may be provided on the semiconductor layer 133. For example, the third insulating material 143a may be provided on the second insulating material 142a and cover the semiconductor layer 133. The third insulating material 143a may be formed over the first area A1 and the second area A2 of the lower substrate 111.

The third insulating material 143a may be a material for forming the gate insulation layer 143 described with reference to FIG. 3.

In addition, the third metal layer 134 may be provided on the third insulating material 143a. In the embodiment, the gate electrode GE of the transistor T may be formed by depositing the third metal layer 134 onto the third insulating material 143a and then patterning at least a part of the third metal layer 134.

Thereafter, with reference further to FIG. 4F, the fourth insulating material 144a may be provided on the third metal layer 134. For example, the fourth insulating material 144a may be provided on the third insulating material 143a and cover the third metal layer 134. The fourth insulating material 144a may be formed over the first area A1 and the second area A2 of the lower substrate 111.

The fourth insulating material 144a may be a material for forming the first interlayer insulation layer 144 described with reference to FIG. 3.

In addition, the fourth metal layer 135 may be provided on the fourth insulating material 144a. In the embodiment, the intermediate metal layer IM and the pad electrode PE may be formed by depositing the fourth metal layer 135 onto the fourth insulating material 144a and then patterning at least a part of the fourth metal layer 135.

Thereafter, the fifth insulating material 145a may be provided on the fourth metal layer 135. For example, the fifth insulating material 145a may be provided on the fourth insulating material 144a and cover the fourth metal layer 135. The fifth insulating material 145a may be formed over the first area A1 and the second area A2 of the lower substrate 111.

The fifth insulating material 145a may be a material for forming the second interlayer insulation layer 145 described with reference to FIG. 3.

In addition, the fifth metal layer 136 may be provided on the fifth insulating material 145a. In the embodiment, the source electrode SE and the drain electrode DE of the transistor T may be formed by depositing the fifth metal layer 136 onto the fifth insulating material 145a and then patterning at least a part of the fifth metal layer 136.

Thereafter, with reference further to FIG. 4G, the sixth insulating material 146a may be provided on the fifth metal layer 136. For example, the sixth insulating material 146a may be provided on the fifth insulating material 145a and cover the fifth metal layer 136. The sixth insulating material 146a may be formed over the first area A1 and the second area A2 of the lower substrate 111.

The sixth insulating material 146a may be a material for forming the third interlayer insulation layer 146 described with reference to FIG. 3.

In addition, the sixth metal layer 137 may be provided on the sixth insulating material 146a. In the embodiment, the first connection pad CNT1 may be formed by depositing the sixth metal layer 137 onto the sixth insulating material 146a and then patterning at least a part of the sixth metal layer 137.

Thereafter, with reference further to FIG. 4H, the seventh insulating material 147a may be provided on the sixth metal layer 137. For example, the seventh insulating material 147a may be provided on the sixth insulating material 146a and cover the sixth metal layer 137. The seventh insulating material 147a may be formed over the first area A1 and the second area A2 of the lower substrate 111.

The seventh insulating material 147a may be an insulating material for forming the passivation layer 147 described with reference to FIG. 3.

Thereafter, with reference further to FIG. 4I, the passivation layer 147 (or seventh insulation layer), the third interlayer insulation layer 146 (or sixth insulation layer), and the second interlayer insulation layer 145 (or fifth insulation layer) may be formed by at least partially removing (e.g., etching) the seventh insulating material 147a, the sixth insulating material 146a, and the fifth insulating material 145a by a first mask MK1.

For example, the passivation layer 147 may be formed by removing a part of the seventh insulating material 147a disposed in a part of the first area A1 and disposed in the second area A2, the third interlayer insulation layer 146 may be formed by removing a part of the sixth insulating material 146a disposed in a part of the first area A1 and disposed in the second area A2, and the second interlayer insulation layer 145 may be formed by removing a part of the fifth insulating material 145a disposed in a part of the first area A1 and disposed in the second area A2. Specifically, the seventh insulating material 147a, the sixth insulating material 146a, and the fifth insulating material 145a disposed in the second area A2 and disposed in a part of the first area A1 adjacent to the second area A2 may be removed.

To this end, a photoresist (PR) is applied onto the seventh insulating material 147a, the sixth insulating material 146a, and the fifth insulating material 145a disposed in the second area A2 and disposed in a part of the first area A1 adjacent to the second area A2, and the seventh insulating material 147a, the sixth insulating material 146a, and the fifth insulating material 145a, which correspond to the second area A2 and correspond to a part of the first area A1 adjacent to the second area A2, are removed (e.g., etched) by using the first mask MK1 having a first mask opening portion OP1-MK that overlaps the second area A2 and overlaps a part of the first area A1 adjacent to the second area A2, such that a first opening portion OP1, which corresponds to the first mask opening portion OP1-MK, may be formed on the seventh insulating material 147a, the sixth insulating material 146a, and the fifth insulating material 145a. Therefore, the passivation layer 147, the third interlayer insulation layer 146, and the second interlayer insulation layer 145 may be formed.

According to the embodiment, the passivation layer 147, the third interlayer insulation layer 146, and the second interlayer insulation layer 145 are etched under a soft etching condition, such that the side surface of each of the passivation layer 147, the third interlayer insulation layer 146, and the second interlayer insulation layer 145 may have a tapered structure having an oblique shape obliquely formed as a whole.

Thereafter, with reference further to FIG. 4J, the first interlayer insulation layer 144 (or fourth insulation layer), the gate insulation layer 143 (or third insulation layer), the second buffer layer 142 (or second insulation layer), and the first buffer layer 141 (or first insulation layer) may be formed by at least partially removing (e.g., etching) the fourth insulating material 144a, the third insulating material 143a, the second insulating material 142a, and the first insulating material 141a by using a second mask MK2.

For example, the first interlayer insulation layer 144 may be formed by removing a part of the fourth insulating material 144a disposed in a part of the first area A1 and disposed in the second area A2, the gate insulation layer 143 may be formed by removing a part of the third insulating material 143a disposed in a part of the first area A1 and disposed in the second area A2, the second buffer layer 142 may be formed by removing a part of the second insulating material 142a disposed in a part of the first area A1 and disposed in the second area A2, and the first buffer layer 141 may be formed by removing a part of the first insulating material 141a disposed in a part of the first area A1 and disposed in the second area A2. Specifically, the fourth insulating material 144a, the third insulating material 143a, the second insulating material 142a, and the first insulating material 141a disposed in the second area A2 and disposed in a part of the first area A1 adjacent to the second area A2 may be removed.

To this end, a photoresist (PR) is applied onto the fourth insulating material 144a, the third insulating material 143a, the second insulating material 142a, and the first insulating material 141a disposed in the second area A2 and disposed in a part of the first area A1 adjacent to the second area A2, and the fourth insulating material 144a, the third insulating material 143a, the second insulating material 142a, and the first insulating material 141a, which correspond to the second area A2 and a part of the first area A1 adjacent to the second area A2, are removed (e.g., etched) by using the second mask MK2 having a second mask opening portion OP2-MK that overlaps the second area A2 and overlaps a part of the first area A1 adjacent to the second area A2, such that a second opening portion OP2, which corresponds to the second mask opening portion OP2-MK, may be formed on the fourth insulating material 144a, the third insulating material 143a, the second insulating material 142a, and the first insulating material 141a. Therefore, the first interlayer insulation layer 144, the gate insulation layer 143, the second buffer layer 142, and the first buffer layer 141 may be formed.

According to the embodiment, the first interlayer insulation layer 144, the gate insulation layer 143, the second buffer layer 142, and the first buffer layer 141 are etched under a soft condition, such that the side surface of each of the first interlayer insulation layer 144, the gate insulation layer 143, the second buffer layer 142, and the first buffer layer 141 may have a tapered structure having an oblique shape obliquely formed as a whole.

Meanwhile, because the first metal layer 131 is disposed on at least a part of the first plate pattern 121 and disposed above the first line pattern 122 during the process of etching the fourth insulating material 144a, the third insulating material 143a, the second insulating material 142a, and the first insulating material 141a including insulating materials, it is possible to inhibit at least a part of the first plate pattern 121 and the first line pattern 122 from being damaged by the first metal layer 131 during the etching process even though the process of etching the fourth insulating material 144a, the third insulating material 143a, the second insulating material 142a, and the first insulating material 141a is performed.

Thereafter, with reference further to FIG. 4K, the protection pattern SLD may be formed by removing (e.g., etching) at least a part of the first metal layer 131 by using a third mask MK3. For example, wet etching is performed on the first metal layer 131 by using the third mask MK3 having a third mask opening portion OP3-MK that overlaps the second area A2 and overlaps a part of the first area A1 adjacent to the second area A2, such that a third opening portion OP3, which corresponds to the third mask opening portion OP3-MK, may be formed on the first metal layer 131, and thus the protection pattern SLD may be formed.

Thereafter, with reference further to FIG. 4L, the planarization layer 148 may be provided on the passivation layer 147. For example, the planarization layer 148 may be formed by forming an insulating material, which constitutes the planarization layer, on the passivation layer 147 and then patterning the insulating material. For example, the planarization layer 148 may be patterned so that a top surface of at least a part of the fifth metal layer 136 (e.g., the drain electrode DE of the transistor T or the like) and a top surface of at least a part of the sixth metal layer 137 (e.g., the first connection pad CNT1 or the like) are exposed.

The planarization layer 148 may be provided to cover the top and side surfaces of the first buffer layer 141, the second buffer layer 142, the gate insulation layer 143, the first interlayer insulation layer 144, the second interlayer insulation layer 145, the third interlayer insulation layer 146, and the passivation layer 147 and cover at least a part of the top surface of the first plate pattern 121. Specifically, the planarization layer 148 may be provided to cover the top and side surfaces of the passivation layer 147, the side surface of the third interlayer insulation layer 146, the side surface of the second interlayer insulation layer 145, the side surface of the first interlayer insulation layer 144, the side surface of the gate insulation layer 143, the side surface of the second buffer layer 142, the side surface of the first buffer layer 141, and a part of the top surfaces of the plurality of first plate patterns 121. For example, the planarization layer 148 may be provided to cover the portion corresponding to the area of the top surfaces of the plurality of first plate patterns 121 spaced apart from the boundary between the first area A1 and the second area A2 at the predetermined interval d. In addition, the planarization layer 148 may not be provided in the second area A2.

Thereafter, the seventh metal layer 138 may be provided on the planarization layer 148. For example, the seventh metal layer 138 including the second connection pad CNT2 and the connection lines CL1 (not shown in FIG. 4L) and CL2 may be provided on the planarization layer 148.

The connection lines CL1 and CL2 may be provided on the first line pattern 122, which is disposed in the second area A2, and at least a part of the first plate pattern 121, which is disposed in the first area A1, and electrically connect the pads (e.g., the pad electrodes PE) disposed on the adjacent first plate patterns 121.

Meanwhile, although not illustrated in FIGS. 4A to 4L, after the seventh metal layer 138 is provided, the process of providing the bank 149, the LED 170, the upper substrate 112, and the like, which have been described with reference to FIG. 3, on the seventh metal layer 138 may be performed, and the display device 100 may be manufactured by a laser-lift-off (LLO) process of separating the sacrificial layer SFL and the mother substrate MSB from the lower substrate 111 of the display device 100.

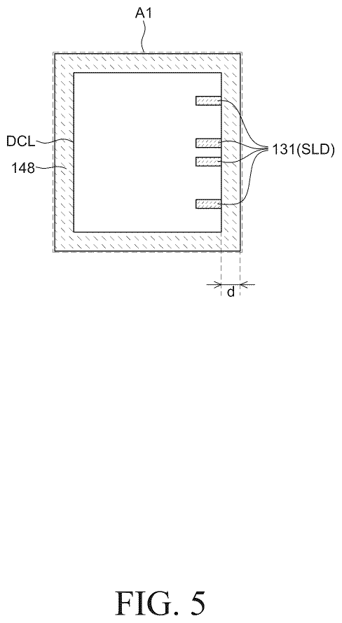

FIG. 5 is a view for explaining an example of the protection pattern included in the display device in FIG. 3 according to one embodiment.

Meanwhile, FIG. 5 illustrates an example of an arrangement relationship, in a plan view, between the first metal layer 131, the circuit element layer DCL, and the planarization layer 148 disposed in the first area A1 among the components included in the display device 100 in FIG. 3.

With reference to FIG. 5, the circuit element layer DCL may be disposed in the first area A1, and the planarization layer 148 may be disposed on the circuit element layer DCL. In this case, as described with reference to FIG. 3, the planarization layer 148 is disposed to surround the first buffer layer 141, the second buffer layer 142, the gate insulation layer 143, the first interlayer insulation layer 144, the second interlayer insulation layer 145, the third interlayer insulation layer 146, and the passivation layer 147 together with the plurality of first plate patterns 121, such that the planarization layer 148 may be disposed to surround the circuit element layer DCL. For example, in a plan view, the circuit element layer DCL, e.g., the first buffer layer 141 may overlap the planarization layer 148 and be spaced apart from the planarization layer 148 at the predetermined interval d.

In addition, the first metal layer 131 may include the protection pattern SLD. In a plan view, the protection pattern SLD may be spaced apart from the planarization layer 148 at the predetermined interval d. For example, the protection pattern SLD is formed by removing (e.g., etching) the first metal layer 131 disposed in the second area A2 and disposed in a part of the first area A1 in which the circuit element layer DCL (e.g., the first buffer layer 141) is not disposed, such that the protection pattern SLD may be disposed to overlap the circuit element layer DCL, e.g., the first buffer layer 141 and be spaced apart from the planarization layer 148 at the predetermined interval d in a plan view.

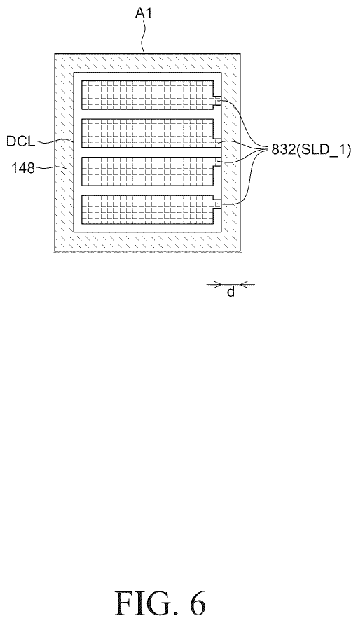

FIG. 6 is a view for explaining another example of the protection pattern included in the display device in FIG. 3 according to one embodiment.

Meanwhile, FIG. 6 illustrates a modified embodiment of the protection pattern SLD described with reference to FIGS. 3 to 5 in relation to a protection pattern SLD_1. Therefore, redundant descriptions will not be repeated.

Meanwhile, FIG. 6 illustrates an example of an arrangement relationship, in a plan view, between a second metal layer 832, the circuit element layer DCL, and the planarization layer 148 disposed in the first area A1 among the components included in the display device 100 in FIG. 3.

With reference to FIG. 6, the circuit element layer DCL may be disposed in the first area A1, and the planarization layer 148 may be disposed on the circuit element layer DCL.

In the embodiment, the protection pattern SLD may be configured as the second metal layer 832. For example, unlike the configuration illustrated in FIGS. 3 to 5, the first metal layer 131 is not separately deposited during the process of manufacturing the display device 100. The protection pattern SLD_1 may be formed by performing wet etching on at least a part of the second metal layer 832 by using the third mask MK3 after a process of forming the first buffer layer 141, the second buffer layer 142, the gate insulation layer 143, and the first interlayer insulation layer 144 by depositing the second metal layer 832 on the pattern layer 120 over a partial area of the first area A1 and the second area A2 and then etching the first to fourth insulating materials 141a, 142a, 143a, and 144a during the process of manufacturing the second metal layer 832.

In this case, the process of manufacturing the display device 100 may be further simplified because a separate metal layer (e.g., the first metal layer 131) for suppressing damage to the first line pattern 122 and at least a part of the first plate pattern 121 included in the pattern layer 120 may not be additionally deposited during the process of etching the first to fourth insulating materials 141a, 142a, 143a, and 144a.

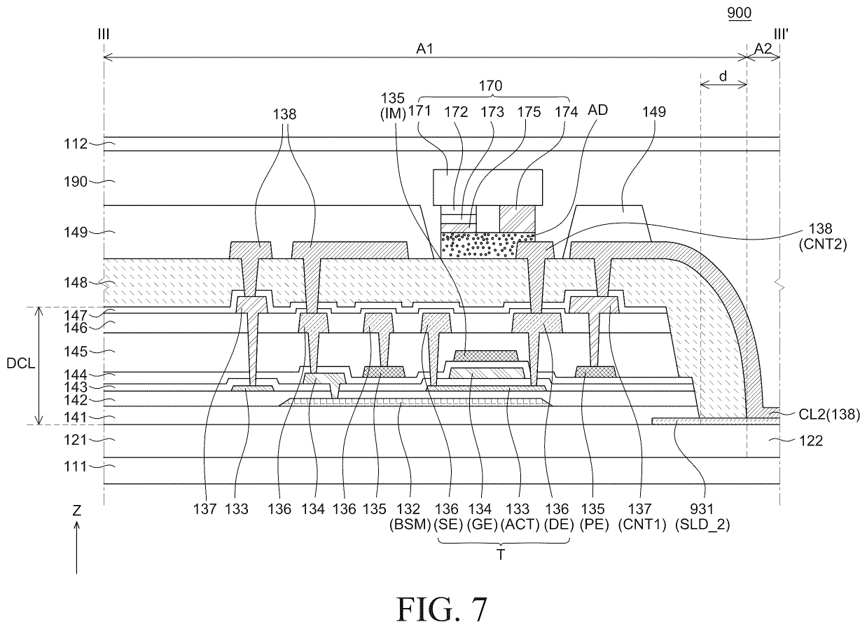

FIG. 7 is a cross-sectional view illustrating another example taken along line III-III′ illustrated in FIG. 2 according to one embodiment.

Meanwhile, FIG. 7 illustrates a cross-sectional structure of a display device 900 according to another embodiment of the present disclosure. For example, the display device 900 illustrated in FIG. 7 is a modified embodiment of the display device 100 described with reference to FIG. 3 in relation to an arrangement area of a first metal layer 931 (e.g., a protection pattern SLD_2). Therefore, redundant descriptions will not be repeated.

With reference to FIG. 7, the first metal layer 931 may be disposed in a partial area of the first area A1, in which the plurality of first plate patterns 121 is disposed, and disposed in the second area A2 in which the plurality of first line patterns 122 are disposed.

The first metal layer 931 may include the protection pattern SLD_2. As described above, the protection pattern SLD_2 may be included in a part of the first metal layer 931 formed over the upper portion of the first line pattern 122 and a part of the first plate pattern 121 adjacent to the first line pattern 122 in order to suppress damage to the pattern layer 120, e.g., the first line pattern 122 caused by the process of etching the plurality of insulation layers disposed in the second area A2 in which the first line pattern 122 is disposed during the process of manufacturing the display device 900.

In one embodiment, unlike the display device 100 described with reference to FIG. 3, the process of removing (e.g., etching) the first metal layer 931 may be excluded in the case of the display device 900 according to another embodiment of the present disclosure, as illustrated in FIG. 7. Therefore, the first metal layer 931, e.g., the protection pattern SLD_2 may be disposed in a partial area of the first area A1, in which the plurality of first plate patterns 121 is disposed and disposed in the second area A2 in which the plurality of first line patterns 122 are disposed. In addition, the process of removing (e.g., etching) the first metal layer 931 may be excluded.

Therefore, as illustrated in FIG. 7, a part of the top surface of the first metal layer 931 may be covered by the first buffer layer 141, another part of the top surface of the first metal layer 931 may be covered by the planarization layer 148, and still another part of the top surface of the first metal layer 931 may be covered by the connection lines CL1 (not shown in FIG. 7) and CL2 of the seventh metal layer 138. For example, the first metal layer 931 may be disposed between the first plate pattern 121 and the first buffer layer 141 and between the first plate pattern 121 and the planarization layer 148 in the first area A1 and disposed between the first line pattern 122 and the connection lines CL1 and CL2 in the second area A2.

More specifically, as illustrated in FIG. 7, the planarization layer 148 may be disposed to cover the top surface of the insulation layer, which is disposed on the uppermost portion among the plurality of insulation layers included in the circuit element layer DCL, the side surface of each of the plurality of insulation layers, and a part of the top surface of the first metal layer 931 disposed in the first area A1. For example, the planarization layer 148 may be disposed to cover the top and side surfaces of the passivation layer 147, the side surface of the third interlayer insulation layer 146, the side surface of the second interlayer insulation layer 145, the side surface of the first interlayer insulation layer 144, the side surface of the gate insulation layer 143, the side surface of the second buffer layer 142, the side surface of the first buffer layer 141, and a part of the top surface of the first metal layer 931.

In addition, as illustrated in FIG. 7, the connection lines CL1 and CL2 may be disposed to extend from the top surface of the first metal layer 931 disposed in the second area A2 to the side and top surfaces of the planarization layer 148. For example, the connection lines CL1 and CL2 may be disposed to adjoin the top and side surfaces of the planarization layer 148 disposed on the first plate pattern 121, and the connection lines CL1 and CL2 may be formed to extend to the top surface of the first metal layer 931 disposed on the first line pattern 122. For example, the connection lines CL1 and CL2 may be disposed to directly adjoin the top surface of the first metal layer 931 disposed the first line pattern 122. That is, the first line pattern 122 and the connection lines CL1 and CL2 may be spaced apart from each other, and the first metal layer 931 may be disposed between the first line pattern 122 and the connection lines CL1 and CL2.

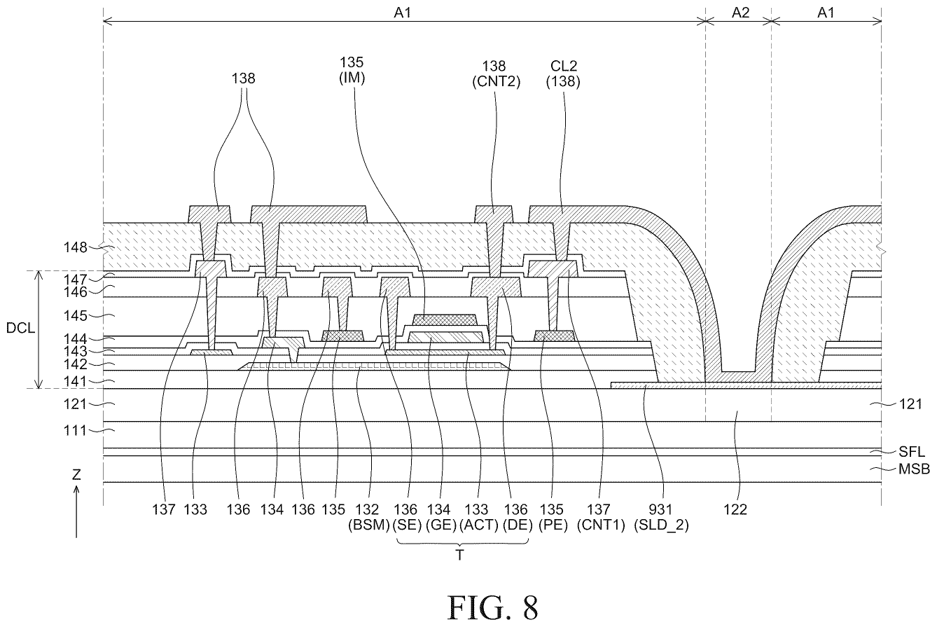

FIG. 8 is a process diagram illustrating a method of manufacturing the display device according to embodiments of the present disclosure.

Meanwhile, FIG. 8 is a cross-sectional view of a process of manufacturing the display device 900 according to another embodiment of the present disclosure described with reference to FIG. 7. For example, the process of removing (e.g., etching) the first metal layer 931 may be excluded in the case of the display device 900 according to another embodiment of the present disclosure described above with reference to FIG. 7. Therefore, the process of manufacturing the display device 100 according to the embodiment of the present disclosure described with reference to FIGS. 4A to 4J may be performed in a substantially equal or similar manner to the process of manufacturing the display device 900 according to another embodiment of the present disclosure. Therefore, FIG. 8 is a cross-sectional view illustrating the process of manufacturing the display device 900 after the manufacturing process described with reference to FIGS. 4A to 4J.

Meanwhile, for convenience of description, the contents, which are identical to the contents described with reference to FIG. 7, will not be described repeatedly.

With reference to FIG. 8, as described with reference to FIGS. 4A to 4J, the sacrificial layer SFL may be formed on the mother substrate MSB, the lower substrate 111, the pattern layer 120, the first metal layer 931, the first insulating material 141a, the second metal layer 132, the second insulating material 142a, the semiconductor layer 133, the third insulating material 143a, the third metal layer 134, the fourth insulating material 144a, the fourth metal layer 135, the fifth insulating material 145a, the fifth metal layer 136, the sixth insulating material 146a, the sixth metal layer 137, and the seventh insulating material 147a may be sequentially provided on the sacrificial layer SFL, the passivation layer 147, the third interlayer insulation layer 146, and the second interlayer insulation layer 145 may be formed by at least partially removing (e.g., etching) the seventh insulating material 147a, the sixth insulating material 146a, and the fifth insulating material 145a by using the first mask MK1, and the first interlayer insulation layer 144, the gate insulation layer 143, the second buffer layer 142, and the first buffer layer 141 may be formed by at least partially removing (e.g., etching) the fourth insulating material 144a, the third insulating material 143a, the second insulating material 142a, and the first insulating material 141a by using the second mask MK2.

Thereafter, the planarization layer 148 may be provided on the passivation layer 147 without the process of removing (e.g., etching) the first metal layer 931. The planarization layer 148 may be provided to cover the top and side surfaces of the first buffer layer 141, the second buffer layer 142, the gate insulation layer 143, the first interlayer insulation layer 144, the second interlayer insulation layer 145, the third interlayer insulation layer 146, and the passivation layer 147 and cover the top surface of the first metal layer 931 disposed on the first plate pattern 121. Specifically, the planarization layer 148 may be provided to cover the top and side surfaces of the passivation layer 147, the side surface of the third interlayer insulation layer 146, the side surface of the second interlayer insulation layer 145, the side surface of the first interlayer insulation layer 144, the side surface of the gate insulation layer 143, the side surface of the second buffer layer 142, the side surface of the first buffer layer 141, and a part of the top surface of the first metal layer 931 disposed on the plurality of first plate patterns 121.

Thereafter, the seventh metal layer 138 may be provided on the planarization layer 148. For example, the seventh metal layer 138 including the second connection pad CNT2 and the connection lines CL1 (not shown in FIG. 8) and CL2 may be provided on the planarization layer 148.

The connection lines CL1 and CL2 may be provided on the first line pattern 122, which is disposed in the second area A2, and at least a part of the first plate pattern 121, which is disposed in the first area A1, and electrically connect the pads (e.g., the pad electrodes PE) disposed on the adjacent first plate patterns 121.

In the embodiment, the connection lines CL1 and CL2 may be provided to be in direct contact with the top surface of the first metal layer 931 disposed on the first line pattern 122 in the second area A2. That is, the first line pattern 122 and the connection lines CL1 and CL2 may be spaced apart from each other, and the first metal layer 931 may be provided to be disposed between the first line pattern 122 and the connection lines CL1 and CL2.

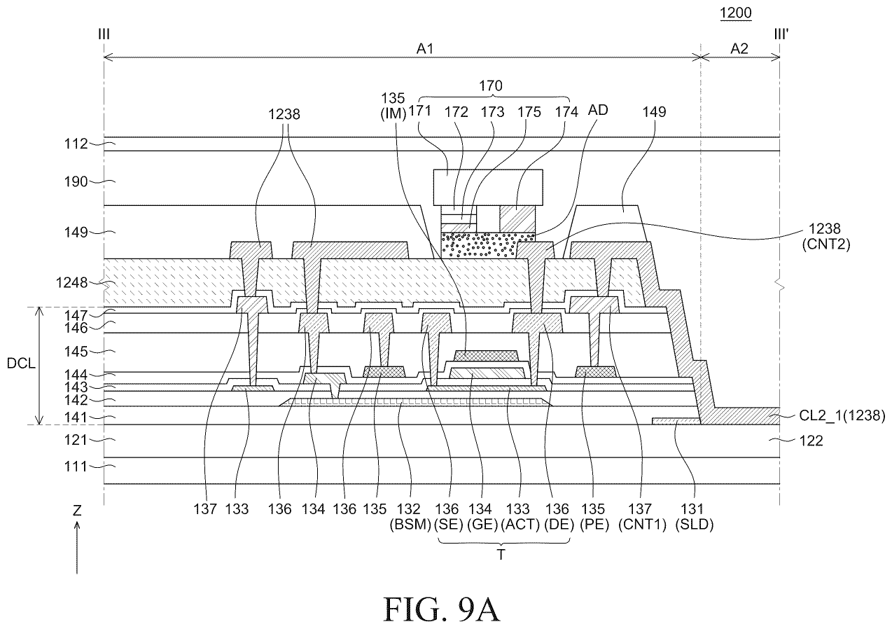

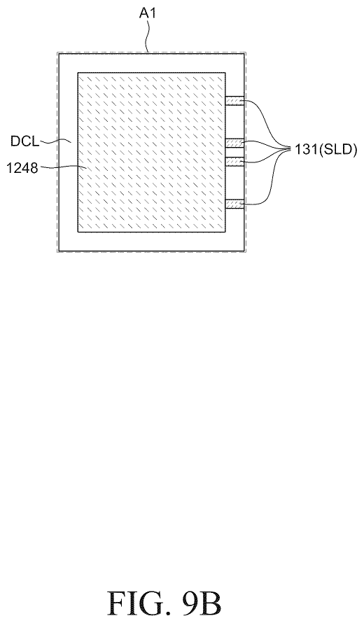

FIG. 9A is a cross-sectional view illustrating still another example taken along line III-III′ illustrated in FIG. 2 according to one embodiment.

FIG. 9B is a view for explaining an example of a protection pattern included in the display device in FIG. 9A according to one embodiment.

Meanwhile, FIG. 9A illustrates a cross-sectional structure of a display device 1200 according to still another embodiment of the present disclosure. For example, the display device 1200 illustrated in FIG. 9A is a modified embodiment of the display device 100 described with reference to FIG. 3 in relation to an arrangement area of a planarization layer 1248. Therefore, redundant descriptions will not be repeated.

Meanwhile, FIG. 9B illustrates an example of an arrangement relationship, in a plan view, between the first metal layer 131, the circuit element layer DCL, and the planarization layer 1248 disposed in the first area A1 among the components included in the display device 1200 in FIG. 9A.

With reference to FIG. 9A, the planarization layer 1248 may be disposed on the circuit element layer DCL. For example, the planarization layer 1248 may be formed on the passivation layer 147.

In the embodiment, the planarization layer 1248 may be disposed to cover the top surface of the insulation layer disposed on the uppermost portion among the plurality of insulation layers included in the circuit element layer DCL. For example, the planarization layer 1248 may be disposed on the plurality of first plate patterns 121 and cover a part of the top surface of the passivation layer 147.

In the embodiment, the planarization layer 1248 may be patterned and formed in an area that overlaps the plurality of first plate patterns 121 (e.g., the first area A1). For example, unlike the display device 100 described with reference to FIG. 3, in the case of the display device 1200 according to still another embodiment of the present disclosure, the planarization layer 1248 may not be formed on the side surfaces of the first buffer layer 141, the second buffer layer 142, the gate insulation layer 143, the first interlayer insulation layer 144, the second interlayer insulation layer 145, the third interlayer insulation layer 146, and the passivation layer 147. For example, during the process of manufacturing the planarization layer 1248, the planarization layer 1248 may be formed by providing the insulating material, which constitutes the planarization layer, on the passivation layer 147 and then patterning the insulating material.

Therefore, a second connection line CL2_1 included in a seventh metal layer 1238 may be disposed to extend from the first line pattern 122 to the side surface of each of the plurality of insulation layers included in the circuit element layer DCL and the side and top surfaces of the planarization layer 1248. For example, the second connection line CL2_1 included in the seventh metal layer 1238 may be disposed to adjoin a part of the top surface of the passivation layer 147 (e.g., the top surface of the passivation layer 147 on which the planarization layer 1248 is not disposed), the side surface of the passivation layer 147, the side surface of the third interlayer insulation layer 146, the side surface of the second interlayer insulation layer 145, the side surface of the first interlayer insulation layer 144, the side surface of the gate insulation layer 143, the side surface of the second buffer layer 142, and the side surface of the first buffer layer 141 from the top and side surfaces of the planarization layer 1248 disposed on the first plate pattern 121, and the second connection line CL2_1 may be formed to extend to the top surface of the first line pattern 122 disposed in the second area A2.

Meanwhile, in a general stretchable display device, a planarization layer is deposited not only to planarize an upper portion of a circuit element layer DCL but also to reinforce a boundary between a first line pattern and a first plate pattern damaged during a process of etching insulating materials. In the case of the display device 1200 according to the embodiment of the present disclosure, the first metal layer 131 protects the first line pattern 122 and the first plate pattern 121 and suppresses damage to the first line pattern 122 and the first plate pattern 121 during the process of etching the insulating materials during the process of manufacturing the display device 1200. Therefore, it is possible to manufacture the display device 1200 in which damage to the first line pattern 122 and the first plate pattern 121 is minimized (e.g., eliminated) or at least reduced even though the planarization layer 1248 is not formed on the boundary between the first plate pattern 121 and the first line pattern 122, e.g., the top surface of the portion of the first plate pattern 121 adjacent to the first line pattern 122.

In addition, with reference to FIG. 9B together, the planarization layer 1248 is formed only on a part of the top surface of the passivation layer 147 without being formed on the side surfaces of the first buffer layer 141, the second buffer layer 142, the gate insulation layer 143, the first interlayer insulation layer 144, the second interlayer insulation layer 145, the third interlayer insulation layer 146, and the passivation layer 147, such that the planarization layer 1248 may overlap the circuit element layer DCL in a plan view and be formed within a narrower range than the circuit element layer DCL, e.g., the first buffer layer 141, the second buffer layer 142, the gate insulation layer 143, the first interlayer insulation layer 144, the second interlayer insulation layer 145, the third interlayer insulation layer 146, and the passivation layer 147 included in the circuit element layer DCL. For example, as illustrated in FIG. 9B, in a plan view, the circuit element layer DCL may be disposed to have a shape that surrounds the planarization layer 1248.

Therefore, the protection pattern SLD included in the first metal layer 131 may be disposed so as not to overlap (e.g., non-overlapping) the planarization layer 1248 in a plan view. For example, because the planarization layer 1248 is disposed only on a part of the top surface of the passivation layer 147, the protection pattern SLD may be disposed to overlap the circuit element layer DCL without overlapping the planarization layer 1248 in a plan view.

In addition, as illustrated in FIGS. 9A and 9B, because the planarization layer 1248 is disposed only on a part of the top surface of the passivation layer 147, an end of the protection pattern SLD included in the first metal layer 131 may adjoin the boundary between the first area A1 and the second area A2, i.e., the boundary between the first plate pattern 121 and the first line pattern 122.

As described above, in the case of the display device 1200 according to still another embodiment of the present disclosure, the first plate pattern 121 may be formed to ensure only an area in which the circuit element layer DCL is disposed without an additional area in which the planarization layer 1248 needs to be disposed. That is, the first plate pattern 121 included in the display device 1200 according to still another embodiment of the present disclosure does not need to ensure an area corresponding to the predetermined interval d described with reference to FIG. 3. Therefore, the size and/or area of the first plate pattern 121 may be reduced, and a high-resolution display device 1200 may be implemented.

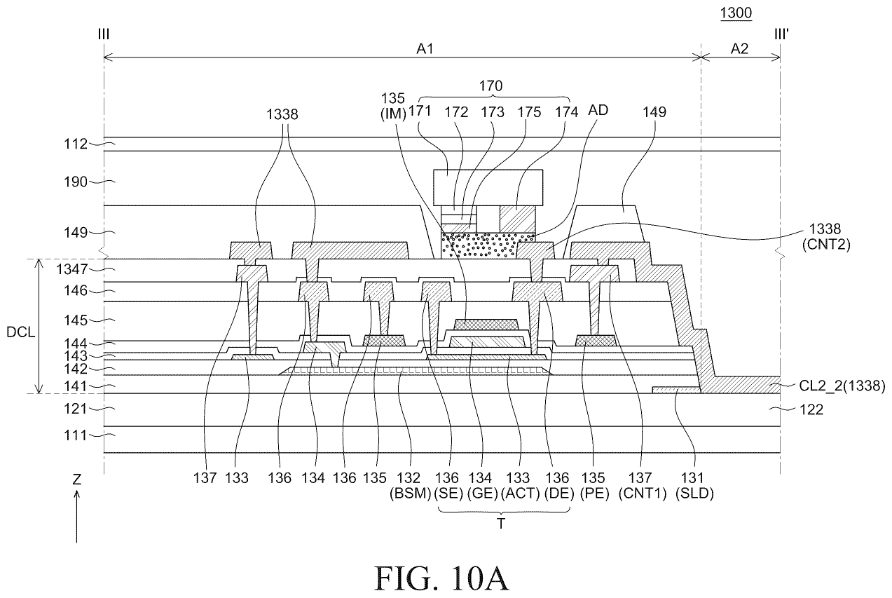

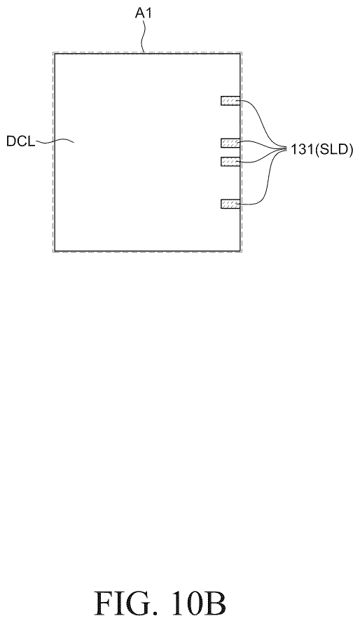

FIG. 10A is a cross-sectional view illustrating yet another example taken along line III-III′ illustrated in FIG. 2 according to one embodiment.

FIG. 10B is a view for explaining an example of a protection pattern included in the display device in FIG. 10A according to one embodiment.

Meanwhile, FIG. 10A illustrates a cross-sectional structure of a display device 1300 according to yet another embodiment of the present disclosure. For example, the display device 1300 illustrated in FIG. 10A is a modified embodiment of the display device 100 described with reference to FIG. 3 in relation to a configuration including no separate planarization layer. Therefore, redundant descriptions will not be repeated.

Meanwhile, FIG. 10B illustrates an example of an arrangement relationship, in a plan view, between the first metal layer 131 and the circuit element layer DCL disposed in the first area A1 among the components included in the display device 1300 in FIG. 10A.

With reference to FIG. 10A, a passivation layer 1347 may be disposed on the third interlayer insulation layer 146 of the circuit element layer DCL. For example, the passivation layer 1347 may be disposed on the third interlayer insulation layer 146 and cover the sixth metal layer 137.

The display device 1300 according to yet another embodiment of the present disclosure in FIGS. 10A and 10B does not include a separate planarization layer, and the passivation layer 1347 may serve as a planarization layer. That is, the passivation layer 1347 may be disposed on the uppermost portion of the circuit element layer DCL and planarize the upper portion of the circuit element layer DCL. Therefore, as illustrated in FIG. 10A, the passivation layer 1347 may have a flat top surface. As illustrated in FIGS. 10A and 10B, the display device 1300 may not include a separate planarization layer.

Therefore, a second connection line CL2_2 included in a seventh metal layer 1338 may be disposed to extend from the first line pattern 122 to the side surface of each of the plurality of insulation layers included in the circuit element layer DCL and the top surface of the insulation layer disposed on the uppermost portion among the plurality of insulation layers. For example, the second connection line CL2_2 included in the seventh metal layer 1338 may be disposed to adjoin the side surface of the third interlayer insulation layer 146, the side surface of the second interlayer insulation layer 145, the side surface of the first interlayer insulation layer 144, the side surface of the gate insulation layer 143, the side surface of the second buffer layer 142, and the side surface of the first buffer layer 141 from the top and side surfaces of the passivation layer 1347 disposed on the first plate pattern 121, and the second connection line CL2_2 may be formed to extend to the top surface of the first line pattern 122 disposed in the second area A2.

Meanwhile, in a general stretchable display device, a planarization layer is deposited to planarize an upper portion of a circuit element layer DCL and also to reinforce a boundary between a first line pattern and a first plate pattern damaged during a process of etching insulating materials. In the case of the display device 1300 according to the embodiment of the present disclosure, the passivation layer 1347 serves to planarize the upper portion of the circuit element layer DCL, and the first metal layer 131 protects the first line pattern 122 and the first plate pattern 121 and suppresses damage to the first line pattern 122 and the first plate pattern 121 during the process of etching the insulating materials during the process of manufacturing the display device 1300. Therefore, it is possible to manufacture the display device 1300 in which the upper portion of the circuit element layer DCL is planarized and damage to the first line pattern 122 and the first plate pattern 121 is minimized (e.g., eliminated) or at least reduced even though a separate planarization layer is not provided.

In addition, with reference to FIG. 10B together, because the display device 1300 does not include a separate planarization layer in the case of the display device 1300 according to yet another embodiment of the present disclosure, the first plate pattern 121 may be formed to ensure only the area in which the circuit element layer DCL is disposed without an additional area in which the planarization layer needs to be disposed. That is, the first plate pattern 121 included in the display device 1300 according to yet another embodiment of the present disclosure does not need to ensure an area corresponding to the predetermined interval d described with reference to FIG. 3. Therefore, the size and/or area of the first plate pattern 121 may be reduced, and a high-resolution display device 1300 may be implemented.

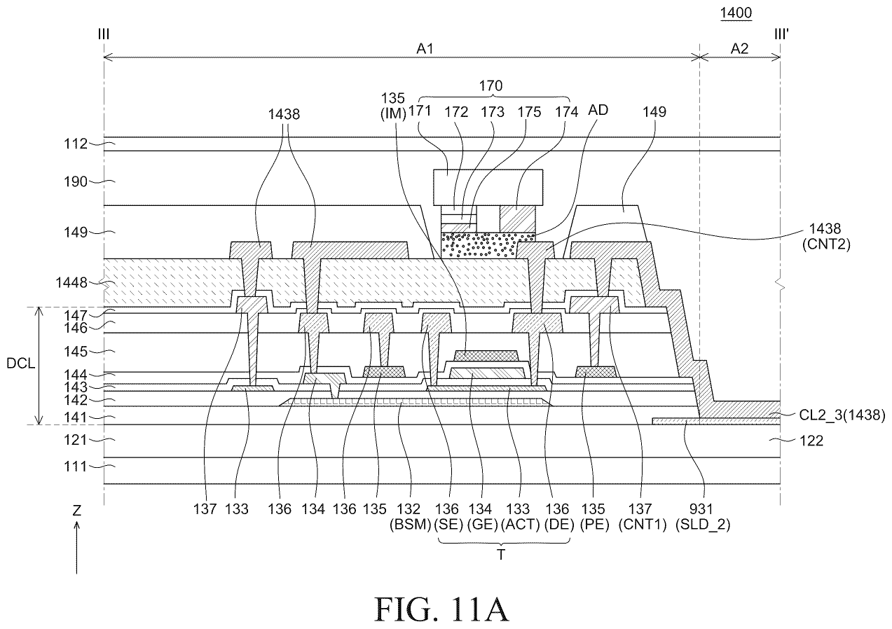

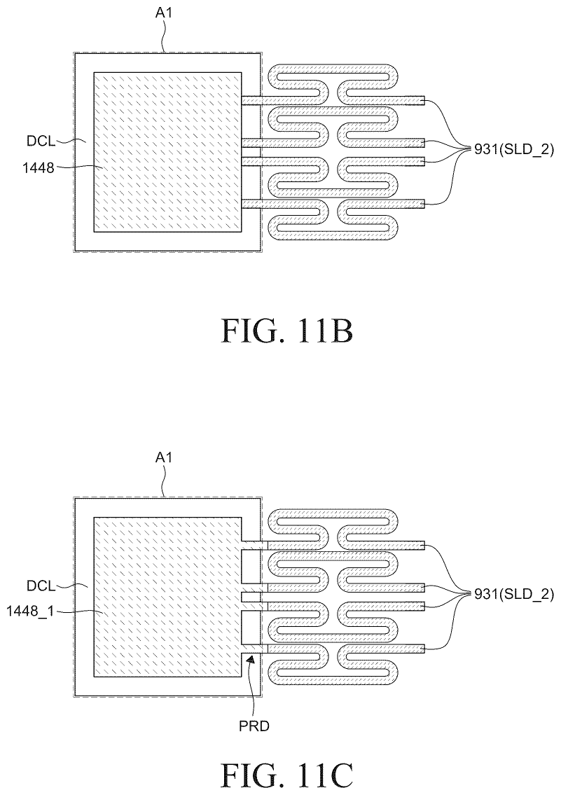

FIG. 11A is a cross-sectional view illustrating still yet another example taken along line III-III′ illustrated in FIG. 2 according to one embodiment.

FIG. 11B is a view for explaining an example of a protection pattern included in the display device in FIG. 11A according to one embodiment.

FIG. 11C is a view for explaining another example of the protection pattern included in the display device in FIG. 11A according to one embodiment.

Meanwhile, FIG. 11A illustrates a cross-sectional structure of a display device 1400 according to still yet another embodiment of the present disclosure. For example, the display device 1400 illustrated in FIG. 11A is a modified embodiment of the display device 900 described with reference to FIG. 7 in relation to an arrangement area of a planarization layer 1448. Therefore, redundant descriptions will not be repeated.

Meanwhile, FIGS. 11B and 11C illustrate an example of an arrangement relationship, in a plan view, between the first metal layer 931, the circuit element layer DCL, and planarization layers 1448 and 1448_1 disposed in the first area A1 among the components included in the display device 1400 in FIG. 11A.

With reference to FIG. 11A, the planarization layer 1448 may be disposed on the circuit element layer DCL. For example, the planarization layer 1448 may be formed on the passivation layer 147.

In the embodiment, the planarization layer 1448 may be disposed to cover the top surface of the insulation layer disposed on the uppermost portion among the plurality of insulation layers included in the circuit element layer DCL. For example, the planarization layer 1448 may be disposed on the plurality of first plate patterns 121 and cover a part of the top surface of the passivation layer 147.

In the embodiment, the planarization layer 1448 may be patterned and formed only in an area that overlaps the plurality of first plate patterns 121 (e.g., the first area A1). For example, unlike the display device 900 described with reference to FIG. 7, in the case of the display device 1400 according to still yet another embodiment of the present disclosure, the planarization layer 1448 may not be formed on the side surfaces of the first buffer layer 141, the second buffer layer 142, the gate insulation layer 143, the first interlayer insulation layer 144, the second interlayer insulation layer 145, the third interlayer insulation layer 146, and the passivation layer 147. For example, during the process of manufacturing the planarization layer 1448, the planarization layer 1448 may be formed by providing the insulating material, which constitutes the planarization layer, on the passivation layer 147 and then patterning the insulating material.

Therefore, a second connection line CL2_3 included in a seventh metal layer 1438 may be disposed to extend from the top surface of the first metal layer 931 disposed in the second area A2 to the side surface of each of the plurality of insulation layers included in the circuit element layer DCL and the side and top surfaces of the planarization layer 1448. For example, the second connection line CL2_3 included in the seventh metal layer 1438 may be disposed to adjoin a part of the top surface of the passivation layer 147 (e.g., the top surface of the passivation layer 147 on which the planarization layer 1448 is not disposed), the side surface of the passivation layer 147, the side surface of the third interlayer insulation layer 146, the side surface of the second interlayer insulation layer 145, the side surface of the first interlayer insulation layer 144, the side surface of the gate insulation layer 143, the side surface of the second buffer layer 142, and the side surface of the first buffer layer 141 from the top and side surfaces of the planarization layer 1448 disposed on the first plate pattern 121, and the second connection line CL2_3 may be formed to extend to the top surface of the first metal layer 931 disposed in the second area A2.

Meanwhile, in a general stretchable display device, a planarization layer is deposited not only to planarize an upper portion of a circuit element layer DCL but also to reinforce a boundary between a first line pattern and a first plate pattern damaged during a process of etching insulating materials. In the case of the display device 1400 according to the embodiment of the present disclosure, the first metal layer 931 protects the first line pattern 122 and the first plate pattern 121 and suppresses damage to the first line pattern 122 and the first plate pattern 121 during the process of etching the insulating materials during the process of manufacturing the display device 1400. Therefore, it is possible to manufacture the display device 1400 in which damage to the first line pattern 122 and the first plate pattern 121 is minimized (e.g., eliminated) even though the planarization layer 1448 is not formed on the boundary between the first plate pattern 121 and the first line pattern 122, e.g., the top surface of the portion of the first plate pattern 121 adjacent to the first line pattern 122.

In addition, with reference to FIG. 11B together, the planarization layer 1448 is formed on a part of the top surface of the passivation layer 147 without being formed on the side surfaces of the first buffer layer 141, the second buffer layer 142, the gate insulation layer 143, the first interlayer insulation layer 144, the second interlayer insulation layer 145, the third interlayer insulation layer 146, and the passivation layer 147, such that the planarization layer 1448 may overlap the circuit element layer DCL in a plan view and be formed within a narrower range than the circuit element layer DCL, e.g., the first buffer layer 141, the second buffer layer 142, the gate insulation layer 143, the first interlayer insulation layer 144, the second interlayer insulation layer 145, the third interlayer insulation layer 146, and the passivation layer 147 included in the circuit element layer DCL. For example, as illustrated in FIG. 11B, in a plan view, the circuit element layer DCL may be disposed to have a shape that surrounds the planarization layer 1448.

In addition, the protection pattern SLD_2 included in the first metal layer 931 may be disposed so as not to overlap the planarization layer 1448 in a plan view. For example, because the planarization layer 1448 is disposed only on a part of the top surface of the passivation layer 147, the protection pattern SLD_2 may be disposed to overlap the circuit element layer DCL without overlapping the planarization layer 1448 in a plan view.

As described above, in the case of the display device 1400 according to still yet another embodiment of the present disclosure, the first plate pattern 121 may be formed to ensure an area in which the circuit element layer DCL is disposed without an additional area in which the planarization layer 1448 needs to be disposed. That is, the first plate pattern 121 included in the display device 1400 according to still yet another embodiment of the present disclosure does not need to ensure an area corresponding to the predetermined interval d described with reference to FIG. 7. Therefore, the size and/or area of the first plate pattern 121 may be reduced, and a high-resolution display device 1400 may be implemented.

Meanwhile, the planar shape of the planarization layer 1448 is not limited thereto and may be variously modified and carried out. For example, with reference further to FIG. 11C, the planarization layer 1448_1 may include at least one protruding portion PRD protruding in one direction. The protruding portion PRD may be disposed in a partial area of the boundary between the first plate pattern 121 and the first line pattern 122, e.g., the top surface of the portion of the first plate pattern 121 adjacent to the first line pattern 122 and connected to the protection pattern SLD_2 of the first metal layer 931. Therefore, the boundary between the first plate pattern 121 and the first line pattern 122 may be further reinforced.

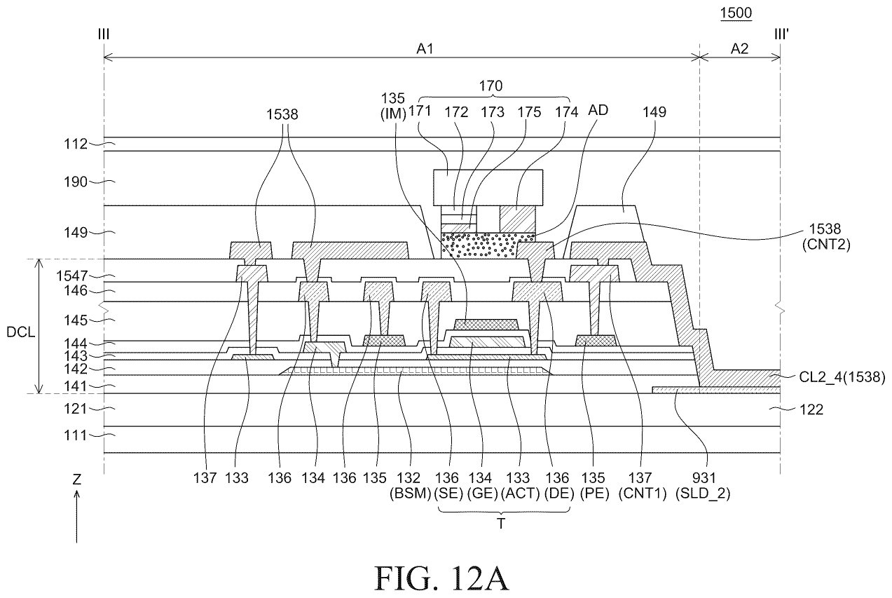

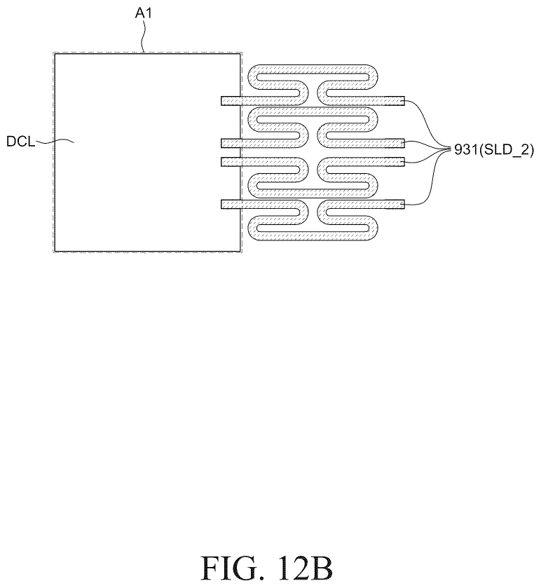

FIG. 12A is a cross-sectional view illustrating a further example taken along line III-III′ illustrated in FIG. 2 according to one embodiment.

FIG. 12B is a view for explaining an example of a protection pattern included in the display device in FIG. 12A according to one embodiment.

Meanwhile, FIG. 12A illustrates a cross-sectional structure of a display device 1500 according to the further embodiment of the present disclosure. For example, the display device 1500 illustrated in FIG. 12A is a modified embodiment of the display device 900 described with reference to FIG. 7 in relation to a configuration including no separate planarization layer. Therefore, redundant descriptions will not be repeated.

Meanwhile, FIG. 12B illustrates an example of an arrangement relationship, in a plan view, between the first metal layer 931 and the circuit element layer DCL disposed in the first area A1 among the components included in the display device 1500 in FIG. 12A.

With reference to FIG. 12A, a passivation layer 1547 may be disposed on the third interlayer insulation layer 146 of the circuit element layer DCL. For example, the passivation layer 1547 may be disposed on the third interlayer insulation layer 146 and cover the sixth metal layer 137.

The display device 1500 according to the further embodiment of the present disclosure in FIGS. 12A and 12B does not include a separate planarization layer, and the passivation layer 1547 may serve as a planarization layer. That is, the passivation layer 1547 may be disposed on the uppermost portion of the circuit element layer DCL and planarize the upper portion of the circuit element layer DCL. Therefore, as illustrated in FIG. 12A, the passivation layer 1547 may have a flat top surface. As illustrated in FIGS. 12A and 12B, the display device 1500 may not include a separate planarization layer.

Therefore, a second connection line CL2_4 included in a seventh metal layer 1538 may be disposed to extend from the top surface of the first metal layer 931 disposed in the second area A2 to the side surface of each of the plurality of insulation layers included in the circuit element layer DCL and the top surface of the insulation layer disposed on the uppermost portion among the plurality of insulation layers. For example, the second connection line CL2_4 included in the seventh metal layer 1538 may be disposed to adjoin the side surface of the third interlayer insulation layer 146, the side surface of the second interlayer insulation layer 145, the side surface of the first interlayer insulation layer 144, the side surface of the gate insulation layer 143, the side surface of the second buffer layer 142, and the side surface of the first buffer layer 141 from the top and side surfaces of the passivation layer 1547 disposed on the first plate pattern 121, and the second connection line CL2_4 may be formed to extend to the top surface of the first line pattern 122 disposed in the second area A2.

Meanwhile, in a general stretchable display device, a planarization layer is deposited to planarize an upper portion of a circuit element layer DCL and also to reinforce a boundary between a first line pattern and a first plate pattern damaged during a process of etching insulating materials. In the case of the display device 1500 according to the embodiment of the present disclosure, the passivation layer 1547 serves to planarize the upper portion of the circuit element layer DCL, and the first metal layer 931 protects the first line pattern 122 and the first plate pattern 121 and suppresses damage to the first line pattern 122 and the first plate pattern 121 during the process of etching the insulating materials during the process of manufacturing the display device 1500. Therefore, it is possible to manufacture the display device 1500 in which the upper portion of the circuit element layer DCL is planarized and damage to the first line pattern 122 and the first plate pattern 121 is minimized (e.g., eliminated) or at least reduced even though a separate planarization layer is not provided.

In addition, with reference to FIG. 12B together, because the display device 1500 does not include a separate planarization layer in the case of the display device 1500 according to the further embodiment of the present disclosure, the first plate pattern 121 may be formed to ensure only the area in which the circuit element layer DCL is disposed without an additional area in which the planarization layer needs to be disposed. That is, the first plate pattern 121 included in the display device 1500 according to the further embodiment of the present disclosure does not need to ensure an area corresponding to the predetermined interval d described with reference to FIG. 7. Therefore, the size and/or area of the first plate pattern 121 may be reduced, and a high-resolution display device 1500 may be implemented.

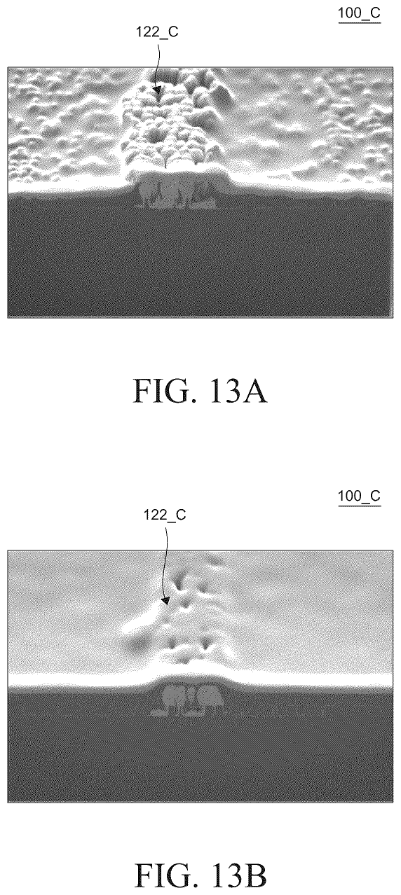

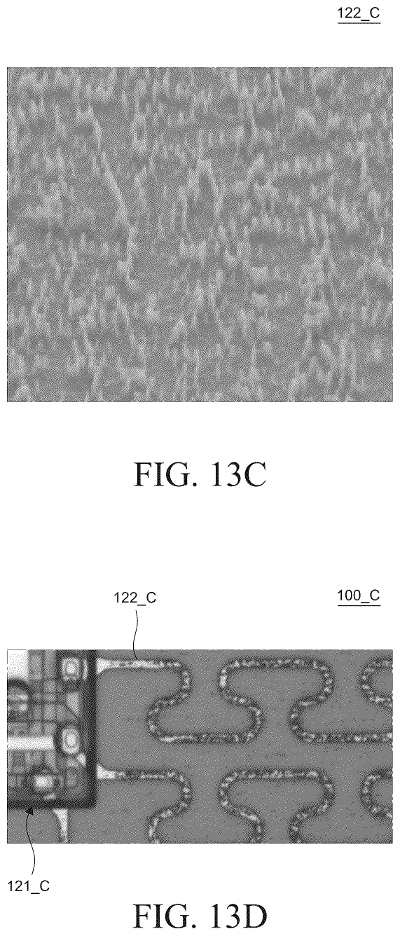

FIGS. 13A to 13D are views for explaining a defective portion of a line pattern included in a display device according to a comparative example of the present disclosure.

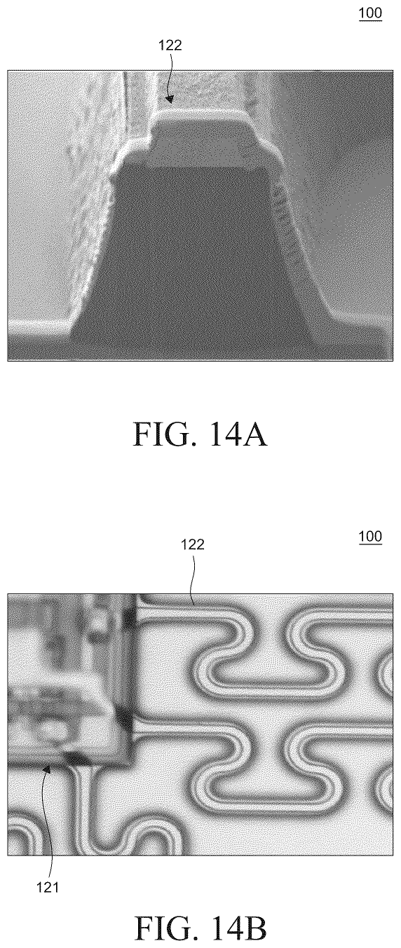

FIGS. 14A and 14B are views for explaining a line pattern included in the display device according to embodiments of the present disclosure.

For example, FIGS. 13A to 13D are micrographs of a first line pattern 122_C included in a display device 100_C according to the comparative example of the present disclosure. FIG. 13A is a micrograph illustrating an example of the first line pattern 122_C according to the comparative example of the present disclosure when viewed from the side surface, FIG. 13B is a micrograph illustrating another example of the first line pattern 122_C according to the comparative example of the present disclosure when viewed from the side surface, FIG. 13C is a micrograph illustrating the first line pattern 122_C according to the comparative example of the present disclosure when viewed from the top surface, and FIG. 13D is a micrograph illustrating a first plate pattern 121_C and the first line pattern 122_C according to the comparative example of the present disclosure when viewed from the top surface.

In addition, FIGS. 14A and 14B are micrographs of the first line pattern 122 included in the display device 100 according to the embodiments of the present disclosure, FIG. 14A is a micrograph illustrating the first line pattern 122 according to the embodiments of the present disclosure when viewed from the side surface, and FIG. 14B is a micrograph illustrating the first plate pattern 121 and the first line pattern 122 according to the embodiment of the present disclosure when viewed from the top surface.

First, with reference to FIGS. 13A to 13D, the display device 100_C according to the comparative example of the present disclosure may correspond to the display device 100_C manufactured by the process of etching and patterning the insulating materials disposed above the first line pattern 122_C in a state in which no separate first metal layer (e.g., protection pattern) is deposited onto the first line pattern 122_C during the process of manufacturing the display device 100_C.

In the case of the display device 100_C according to the comparative example of the present disclosure, a defect may occur in which severe unevenness in the form of columnar joints occurs because a part of the first line pattern 122_C is also etched during the process of etching the insulating materials, as illustrated in FIGS. 13A and 13C. Alternatively, as illustrated in FIG. 13B, a defect in which a depressed portion is formed in the first line pattern 122_C occurs because a part of the first line pattern 122_C is also etched during the process of etching the insulating materials. In this case, as illustrated in FIG. 13D, because the first line pattern 122_C for connecting the adjacent first plate patterns 121_C is damaged without being normally deposited, the stretching reliability of the display device 100_C is not ensured.

In contrast, with reference to FIGS. 14A and 14B, as described above, the display device 100 according to the embodiment of the present disclosure may be manufactured by the process of depositing the first metal layer 131 or 931 (e.g., the protection pattern SLD, SLD_1, or SLD_2) onto the first line pattern 122 and etching and patterning the insulating materials disposed above the first line pattern 122 during the process of manufacturing the display device 100.

Therefore, in the case of the display device 100 according to the embodiments of the present disclosure, as illustrated in FIG. 14A, the first line pattern 122 is protected by the first metal layer 131 or 931 during the process of etching the insulating materials, which may suppress damage caused by the etching process. In this case, as illustrated in FIG. 14B, the first line pattern 122 for connecting the adjacent first plate patterns 121 is normally deposited without being damaged, such that the stretching reliability of the display device 100 may be improved.

As described above, according to the display device and the method of manufacturing the same according to the embodiments of the present disclosure, the process of etching the insulating materials disposed above the line pattern is performed in the state in which the metal layer is disposed above the line pattern, which may inhibit the line pattern and the boundary between the line pattern and the plate pattern from being damaged by the metal layer during the process of etching the insulating material. Therefore, the stretching reliability of the display device may be improved.

In addition, according to the display device and the method of manufacturing the same according to the embodiments of the present disclosure, the line pattern and the boundary between the line pattern and the plate pattern are inhibited from being damaged by the metal layer disposed above the line pattern during the process of etching the insulating material, such that the area, in which the planarization layer is disposed on the plate pattern to reinforce the boundary between the line pattern and the plate pattern, may be minimized, or the planarization layer may be excluded. Therefore, the size and/or area of the plate pattern on which the plurality of pixels is disposed may be reduced, and a high-resolution display device may be implemented.

The display device according to various embodiments of the present disclosure will be described as follows.

In order to achieve the above-mentioned objects, a display device according to an embodiment of the present disclosure may include: a stretchable lower substrate divided into a first area, and a second area different from the first area; a pattern layer disposed on the lower substrate and including a plate pattern disposed in the first area, and a line pattern disposed in the second area; a first metal layer disposed on the plate pattern; a circuit element layer disposed on the plate pattern and the first metal layer and including at least one transistor; a light-emitting element disposed on the circuit element layer; and a connection line disposed on the line pattern and connected to the circuit element layer, in which the first metal layer is in an electrically floating state.

In one embodiment, the first metal layer may be disposed to be spaced apart from a boundary between the first area and the second area at a predetermined interval.

In one embodiment, the display device may further include: a planarization layer disposed between the circuit element layer and the light-emitting element.

In one embodiment, the circuit element layer may include a plurality of insulation layers disposed sequentially, the planarization layer may be disposed to cover a top surface of the insulation layer, which is disposed on an uppermost portion among the plurality of insulation layers, a side surface of each of the plurality of insulation layers, and a part of a top surface of the plate pattern, and the connection line may be disposed to extend from a top surface of the line pattern to side and top surfaces of the planarization layer.

In one embodiment, the circuit element layer may include a plurality of insulation layers disposed sequentially, the planarization layer may be disposed to cover a top surface of the insulation layer disposed on an uppermost portion among the plurality of insulation layers, and the connection line may be disposed to extend from a top surface of the line pattern to a side surface of each of the plurality of insulation layers and side and top surfaces of the planarization layer.

In one embodiment, the first metal layer may not overlap the planarization layer in a plan view.

In one embodiment, the circuit element layer may include a plurality of insulation layers disposed sequentially, and the connection line may be disposed to extend from a top surface of the line pattern to a side surface of each of the plurality of insulation layers and a top surface of the insulation layer disposed on an uppermost portion among the plurality of insulation layers.

In order to achieve the above-mentioned objects, a display device according to an embodiment of the present disclosure may include: a stretchable lower substrate divided into a first area, and a second area different from the first area; a pattern layer disposed on the lower substrate and including a plate pattern disposed in the first area, and a line pattern disposed in the second area; a first metal layer disposed on the plate pattern and the line pattern; a circuit element layer disposed on the plate pattern and the first metal layer and including at least one transistor; a light-emitting element disposed on the circuit element layer; and a connection line disposed on the line pattern and connected to the circuit element layer.

In one embodiment, the first metal layer may be disposed between the line pattern and the connection line in the second area.

In one embodiment, the display device may further include: a planarization layer disposed between the circuit element layer and the light-emitting element.

In one embodiment, the circuit element layer may include a plurality of insulation layers disposed sequentially, the planarization layer may be disposed to cover a top surface of the insulation layer, which is disposed on an uppermost portion among the plurality of insulation layers, a side surface of each of the plurality of insulation layers, and a part of a top surface of the first metal layer disposed in the first area, and the connection line may be disposed to extend from a top surface of the first metal layer disposed in the second area to side and top surfaces of the planarization layer.

In one embodiment, the circuit element layer may include a plurality of insulation layers disposed sequentially, the planarization layer may be disposed to cover a top surface of the insulation layer disposed on an uppermost portion among the plurality of insulation layers, and the connection line may be disposed to extend from a top surface of the first metal layer disposed in the second area to a side surface of each of the plurality of insulation layers and side and top surfaces of the planarization layer.

In one embodiment, the first metal layer may not overlap the planarization layer in a plan view.

In one embodiment, the circuit element layer may include a plurality of insulation layers disposed sequentially, and the connection line may be disposed to extend from a top surface of the first metal layer disposed in the second area to a side surface of each of the plurality of insulation layers and a top surface of the insulation layer disposed on an uppermost portion among the plurality of insulation layers.

The exemplary embodiments of the present disclosure can also be described as follows:

According to an aspect of the present disclosure, there is provided a display device. The display device includes a stretchable lower substrate divided into a first area, and a second area different from the first area. The display device further includes a pattern layer disposed on the lower substrate and comprising a plate pattern disposed in the first area, and a line pattern disposed in the second area. The display device further includes a first metal layer disposed on the plate pattern and a circuit element layer disposed on the plate pattern and the first metal layer and comprising at least one transistor. The display device further includes a light-emitting element disposed on the circuit element layer and a connection line disposed on the line pattern and connected to the circuit element layer. The first metal layer is in an electrically floating state.

The first metal layer may be disposed to be spaced apart from a boundary between the first area and the second area at a predetermined interval.

The display device may further includes a planarization layer disposed between the circuit element layer and the light-emitting element.

The circuit element layer may include a plurality of insulation layers disposed sequentially, the planarization layer may be disposed to cover a top surface of the insulation layer, which is disposed on an uppermost portion among the plurality of insulation layers, a side surface of each of the plurality of insulation layers, and a part of a top surface of the plate pattern, and the connection line may be disposed to extend from a top surface of the line pattern to side and top surfaces of the planarization layer.

The circuit element layer may include a plurality of insulation layers disposed sequentially, the planarization layer may be disposed to cover a top surface of the insulation layer disposed on an uppermost portion among the plurality of insulation layers, and the connection line may be disposed to extend from a top surface of the line pattern to a side surface of each of the plurality of insulation layers and side and top surfaces of the planarization layer.

The first metal layer may not overlap the planarization layer in a plan view.

The circuit element layer may include a plurality of insulation layers disposed sequentially, and the connection line may be disposed to extend from a top surface of the line pattern to a side surface of each of the plurality of insulation layers and a top surface of the insulation layer disposed on an uppermost portion among the plurality of insulation layers.

The display device includes a stretchable lower substrate divided into a first area, and a second area different from the first area and a pattern layer disposed on the lower substrate and comprising a plate pattern disposed in the first area, and a line pattern disposed in the second area. The display device further includes a first metal layer disposed on the plate pattern and the line pattern and a circuit element layer disposed on the plate pattern and the first metal layer and comprising at least one transistor. The display device further includes a light-emitting element disposed on the circuit element layer and a connection line disposed on the line pattern and connected to the circuit element layer.

The first metal layer may be disposed between the line pattern and the connection line in the second area.

The display device may further includes a planarization layer disposed between the circuit element layer and the light-emitting element.

The circuit element layer may include a plurality of insulation layers disposed sequentially, the planarization layer may be disposed to cover a top surface of the insulation layer, which is disposed on an uppermost portion among the plurality of insulation layers, a side surface of each of the plurality of insulation layers, and a part of a top surface of the first metal layer disposed in the first area, and the connection line may be disposed to extend from a top surface of the first metal layer disposed in the second area to side and top surfaces of the planarization layer.

The circuit element layer may include a plurality of insulation layers disposed sequentially, the planarization layer may be disposed to cover a top surface of the insulation layer disposed on an uppermost portion among the plurality of insulation layers, and the connection line may be disposed to extend from a top surface of the first metal layer disposed in the second area to a side surface of each of the plurality of insulation layers and side and top surfaces of the planarization layer.

The first metal layer may not overlap the planarization layer in a plan view.

The circuit element layer may include a plurality of insulation layers disposed sequentially, and the connection line may be disposed to extend from a top surface of the first metal layer disposed in the second area to a side surface of each of the plurality of insulation layers and a top surface of the insulation layer disposed on an uppermost portion among the plurality of insulation layers.

According to an aspect of the present disclosure, there is provided a method of manufacturing a display device. The method of manufacturing a display device includes providing a lower substrate divided into a first area, and a second area different from the first area and providing a pattern layer on the lower substrate, the pattern layer comprising a plate pattern configured to overlap the first area, and a line pattern configured to overlap the second area. The method of manufacturing a display device further includes providing a first metal layer on the pattern layer, the first metal layer being configured to overlap at least a partial area of the first area and the second area and sequentially providing first insulating material, second insulating material, third insulating material, fourth insulating material, fifth insulating material, sixth insulating material and seventh insulating material on the pattern layer and the first metal layer. The method of manufacturing a display device further includes forming a seventh insulation layer, a sixth insulation layer, and a fifth insulation layer on the plate pattern by removing the seventh insulating material, the sixth insulating material, and the fifth insulating material disposed in the second area. The method of manufacturing a display device further includes forming a fourth insulation layer, a third insulation layer, a second insulation layer, and a first insulation layer on the plate pattern by removing the fourth insulating material, the third insulating material, the second insulating material, and the first insulating material disposed in the second area.

The method of manufacturing a display device may further includes forming a protection pattern on the plate pattern by removing the first metal layer disposed in the second area and disposed in a part of the first area adjacent to the second area.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

What is claimed is:

1. A display device comprising:
a stretchable lower substrate divided into a first area and a second area that is different from the first area;
a pattern layer on the stretchable lower substrate, the pattern layer comprising a plate pattern in the first area and a line pattern in the second area;
a first metal layer on the plate pattern;
a circuit element layer on the plate pattern and the first metal layer, the circuit element layer comprising at least one transistor;
a light-emitting element on the circuit element layer; and
a connection line on the line pattern, the connection line connected to the circuit element layer,
wherein the first metal layer is in an electrically floating state.

2. The display device of claim 1, wherein the first metal layer is spaced apart from a boundary between the first area and the second area at a predetermined interval.

3. The display device of claim 1, further comprising:
a planarization layer between the circuit element layer and the light-emitting element.

4. The display device of claim 3, wherein the circuit element layer comprises a plurality of insulation layers disposed sequentially,
wherein the planarization layer covers a top surface of an insulation layer, which is disposed on an uppermost portion among the plurality of insulation layers, a side surface of each of the plurality of insulation layers, and a part of a top surface of the plate pattern, and
wherein the connection line extends from a top surface of the line pattern to side and top surfaces of the planarization layer.

5. The display device of claim 3, wherein the circuit element layer comprises a plurality of insulation layers disposed sequentially,
wherein the planarization layer covers a top surface of an insulation layer disposed on an uppermost portion among the plurality of insulation layers, and
wherein the connection line extends from a top surface of the line pattern to a side surface of each of the plurality of insulation layers and side and top surfaces of the planarization layer.

6. The display device of claim 5, wherein the first metal layer is non-overlapping with the planarization layer in a plan view of the display device.

7. The display device of claim 4, wherein an inclination angle of a side surface of the planarization layer is smaller than inclination angles defined by side surfaces of the plurality of insulation layers.

8. The display device of claim 1, wherein the circuit element layer comprises a plurality of insulation layers disposed sequentially, and
wherein the connection line extends from a top surface of the line pattern to a side surface of each of the plurality of insulation layers and a top surface of an insulation layer disposed on an uppermost portion among the plurality of insulation layers.

9. A display device comprising:
a stretchable lower substrate divided into a first area and a second area that is different from the first area;
a pattern layer on the stretchable lower substrate, the pattern layer comprising a plate pattern in the first area and a line pattern in the second area;
a first metal layer on the plate pattern and the line pattern;
a circuit element layer on the plate pattern and the first metal layer, the circuit element layer comprising at least one transistor;
a light-emitting element on the circuit element layer; and
a connection line on the line pattern, the connection line connected to the circuit element layer.

10. The display device of claim 9, wherein the first metal layer is between the line pattern and the connection line in the second area.

11. The display device of claim 9, further comprising:
a planarization layer between the circuit element layer and the light-emitting element.

12. The display device of claim 11, wherein the circuit element layer comprises a plurality of insulation layers disposed sequentially,
wherein the planarization layer covers a top surface of an insulation layer, which is disposed on an uppermost portion among the plurality of insulation layers, a side surface of each of the plurality of insulation layers, and a part of a top surface of the first metal layer disposed in the first area, and
wherein the connection line extends from a top surface of the first metal layer disposed in the second area to side and top surfaces of the planarization layer.

13. The display device of claim 11, wherein the circuit element layer comprises a plurality of insulation layers disposed sequentially,
wherein the planarization layer covers a top surface of an insulation layer disposed on an uppermost portion among the plurality of insulation layers, and
wherein the connection line extends from a top surface of the first metal layer disposed in the second area to a side surface of each of the plurality of insulation layers and side and top surfaces of the planarization layer.

14. The display device of claim 13, wherein the first metal layer is non-overlapping with the planarization layer in a plan view of the display device.

15. The display device of claim 9, wherein the circuit element layer comprises a plurality of insulation layers disposed sequentially, and
wherein the connection line extends from a top surface of the first metal layer disposed in the second area to a side surface of each of the plurality of insulation layers and a top surface of an insulation layer disposed on an uppermost portion among the plurality of insulation layers.

16. A method of manufacturing a display device, the method comprising:
providing a lower substrate divided into a first area and a second area that is different from the first area;
providing a pattern layer on the lower substrate, the pattern layer comprising a plate pattern that overlaps the first area and a line pattern that overlaps the second area;
providing a first metal layer on the pattern layer, the first metal layer overlapping at least a partial area of the first area and the second area;
sequentially providing a first insulating material, a second insulating material, a third insulating material, a fourth insulating material, a fifth insulating material, a sixth insulating material and a seventh insulating material on the pattern layer and the first metal layer;
forming a seventh insulation layer, a sixth insulation layer, and a fifth insulation layer on the plate pattern by removing the seventh insulating material, the sixth insulating material, and the fifth insulating material disposed in the second area; and
forming a fourth insulation layer, a third insulation layer, a second insulation layer, and a first insulation layer on the plate pattern by removing the fourth insulating material, the third insulating material, the second insulating material, and the first insulating material disposed in the second area.

17. The method of claim 16, further comprising:
forming a protection pattern on the plate pattern by removing the first metal layer disposed in the second area and disposed in a part of the first area adjacent to the second area.
